(19) United States
(12) Patent Application Publication
(10) Pub. No.: US 2024/0324127 A1
(43) Pub. Date: Sep. 26, 2024

(54) FOLDABLE ELECTRONIC DEVICE AND CONTROL METHOD THEREOF

(71) Applicants: Baekeun CHO, Suwon-si (KR); Myunghoon KWAK, Suwon-si (KR); Bohyeon KIM, Suwon-si (KR); Wonkyu SUNG, Suwon-si (KR); Yeonggyu YOON, Suwon-si (KR); Hyunju HONG, Suwon-si (KR)

(72) Inventors: Baekeun CHO, Suwon-si (KR); Myunghoon KWAK, Suwon-si (KR); Bohyeon KIM, Suwon-si (KR); Wonkyu SUNG, Suwon-si (KR); Yeonggyu YOON, Suwon-si (KR); Hyunju HONG, Suwon-si (KR)

(21) Appl. No.: 18/591,874

(22) Filed: Feb. 29, 2024

Related U.S. Application Data
(63) Continuation of application No. PCT/KR2022/013041, filed on Aug. 31, 2002.

(30) Foreign Application Priority Data
Aug. 31, 2021 (KR) 10-2021-0115763

(51) Int. Cl. H05K 5/02; F03G 7/06; G06F 1/16; H05K 5/00

(52) U.S. Cl. CPC H05K 5/0226; F03G 7/06143; G06F 1/1641; G06F 1/1681; H05K 5/0086

(57) ABSTRACT

A foldable electronic device includes a hinge structure, a first housing structure connected to the hinge structure, a second housing structure, which is connected to the hinge structure and is foldable with respect to the first housing structure around the hinge structure, a foldable display disposed on one surface of the first housing structure and one surface of the second housing structure, a first magnetic body portion, which is disposed at a position adjacent to one side edge of the first housing structure and includes a magnetic body arranged in the longitudinal direction of the first housing structure and a second magnetic body portion disposed at a position adjacent to one side edge of the second housing structure and at a position corresponding to the first magnetic body portion and includes a magnetic body arranged in the longitudinal direction of the second housing structure and a power supply circuit.

This application is a Continuation of International Application No. PCT/KR2022/013041, filed on Aug. 31, 2022, in the Korean Intellectual Property Receiving Office and claims priority to Korean Patent Application No. 10-2021-0115763, filed on Aug. 31, 2021, and all the benefits accruing therefrom under 35 U.S.C. § 119, the contents of which in their entirety are herein incorporated by reference.

### TECHNICAL FIELD

The invention relates to a foldable electronic device, more particularly to a foldable electronic device and a method for controlling the same.

### BACKGROUND ART

In line with increasing demands for mobile communication and trends towards highly-integrated electronic devices, various technologies have been developed to improve the portability of electronic devices (for example, mobile communication terminals) and to improve user convenience in connection with use of multimedia functions and the like.

For example, a laptop computer may have an automatic opening module made of a shape memory alloy such that a housing on which a display is installed may be opened automatically, thereby providing user convenience.

There has also been ongoing research such that a foldable electronic device which has a foldable display, and which undergoes frequent opening/closing operations, has an automatic opening module made of a shape memory alloy as in the case of the laptop computer, thereby providing user convenience.

The above-described information may be provided as background art to aid in understanding the invention.

### DETAILED DESCRIPTION OF THE INVENTION

### Technical Problem

In the case of a shape memory alloy-based opening module of an electronic device, temperature is a major factor of the operating mechanism, and the same may thus be heavily affected by ambient temperature. According to the prior art, a shape memory alloy-based automatic opening module of an electronic device may not respond to the temperature of various environments, thereby causing a time delay for operating and restoring. This may degrade opening and/or restoring immediacy, thereby inconveniencing the user.

### Technical Solution

Various embodiments may provide a foldable electronic device including a hinge structure, a first housing structure connected to the hinge structure, a second housing structure connected to the hinge structure and configured to be foldable with respect to the first housing structure around the hinge structure, a foldable display disposed on a surface of the first housing structure and a surface of the second housing structure, a first magnetic body part including a magnetic body which is disposed at a position adjacent to a side edge of the first housing structure and arranged along the longitudinal direction of the first housing structure, and a second magnetic body part including a magnetic body which is disposed at a position adjacent to a side edge of the second housing structure and at a position corresponding to the first magnetic body part and arranged along the longitudinal direction of the second housing structure, wherein at least one of the first magnetic body part or the second magnetic body part is formed as a movable magnetic body module including a power supply circuit and a shape memory alloy wire elongated from one side of the magnetic body along the longitudinal direction of the electronic device.

Various embodiments may provide a method for controlling a foldable electronic device including obtaining at least one of a temperature of or around the electronic device, a tilting state of the electronic device with respect to a direction of gravity, and a folding state of the electronic device, wherein the foldable electronic device comprises a first housing structure and a second housing structure foldable with respect to the first housing structure, and including a processor and an automatic opening module configured to perform an opening operation of the first housing structure with respect to the second housing structure, by using a magnetic body part disposed in each of the first housing structure and the second housing structure and a shape memory alloy member disposed in at least one of the first housing structure or the second housing structure, wherein the processor is configured to adjust a magnitude of power and/or a supply time period of power supplied to the shape memory alloy member, based on at least one element of the temperature of or around the electronic device, the tilting of the electronic device with respect to the direction of gravity, and the folding state of the electronic device.

Various embodiments may provide a foldable electronic device including a hinge structure configured to form a folding axis, a first housing structure which is connected to the hinge structure to be rotatable around the folding axis and includes a first surface configured to face a first direction, a second surface configured to face a second direction opposite to the first direction, and a first side surface disposed to be directed parallel to and spaced apart from the folding axis of the hinge structure, between the first surface and the second surface, a second housing structure which is connected to the hinge structure to be rotatable around the folding axis and includes a third surface configured to face a third direction, a fourth surface configured to face a fourth direction opposite to the third direction and a second side surface disposed to be directed parallel to and spaced apart from the folding axis of the hinge structure, between the third surface and fourth surface, a foldable display disposed on a surface of the first housing structure and a surface of the second housing structure, a power supply circuit, a movable magnetic body module including a magnetic body which is disposed at a position adjacent to the first side surface of the first housing structure and arranged along the longitudinal direction of the first housing structure, and a shape memory alloy member which is electrically connected to the power supply circuit and which is capable of being deformed or restored along the longitudinal direction of the electronic device, and a stationary magnetic body disposed at a position adjacent to a second side surface of the second housing structure and at a position corresponding to the first magnetic body part and arranged along the longitudinal direction of the second housing structure.

### Advantageous Effects

According to various embodiments, user convenience may be improved by providing a foldable electronic device configured such that the electronic device can be automatically opened from a closed state to an open state.

According to various embodiments, immediacy of opening and/or restoring operations may be secured in temperature environments in which a shape memory alloy is used, and appropriate control may be performed according to various tilting and folding states of a foldable electronic device, thereby reducing the time of opening and/or restoring operations and power consumption.

According to various embodiments, an automatic opening module including a shape memory alloy may be used to switch the polarity of a magnetic body array, and driving force of a hinge and repulsive force of a flexible display are used for opening operations, thereby implementing an easy-opening operation in which that the same is automatically opened by a predetermined angle (or predetermined distance), thereby improving usability.

### BRIEF DESCRIPTION OF DRAWINGS

FIG. 1 is a block diagram of an electronic device in a network environment, according to an embodiment.

FIG. 2 is a view illustrating an unfolded state of an electronic device, according to an embodiment.

FIG. 3 is a view illustrating a folded state of an electronic device, according to an embodiment.

FIG. 4 is an exploded perspective view of an electronic device, according to an embodiment.

FIG. 5A is a perspective view illustrating an electronic device opened from a closed state to an open state, according to an embodiment.

FIG. 5B is a view illustrating the shape of a cam included in the hinge structure, according to an embodiment.

FIG. 6 is a view showing the inner shape of an electronic device in an open state, according to an embodiment.

FIG. 7 is a view illustrating a magnetic body array having a Halbach arrangement, according to an embodiment.

FIG. 8A is a view illustrating a movable magnetic body module, according to an embodiment.

FIG. 8B is a view illustrating a movable magnetic body module, according to an embodiment.

FIG. 8C is a view illustrating a movable magnetic body module, according to an embodiment.

FIG. 9 is a view showing an operation of an automatic opening module before feeding and after feeding, according to an embodiment.

FIG. 10 is a view illustrating a cross section taken along the direction B-B′ in the view of FIG. 9, according to an embodiment.

FIG. 11A is a view illustrating an array structure of a magnetic body array, according to an embodiment.

FIG. 11B is a view illustrating an array structure of a magnetic body array, according to an embodiment.

FIG. 12A is an enlarged view of the portion of a support body included in a movable magnetic body module, according to an embodiment.

FIG. 12B is a view showing a state in which a shape memory alloy wire is seated on a support body, according to an embodiment.

FIG. 13A is a view illustrating automatic opening modules, according to an embodiment.

FIG. 13B is a view illustrating automatic opening modules, according to an embodiment.

FIG. 14 is a view illustrating various folded states of an electronic device and the tilt thereof with respect to the direction of gravity, according to an embodiment.

FIG. 15 is a flowchart of a control method of a foldable electronic device, according to an embodiment.

### MODE FOR CARRYING OUT THE INVENTION

Hereinafter, embodiments of the invention will be described with reference to the accompanying drawings.

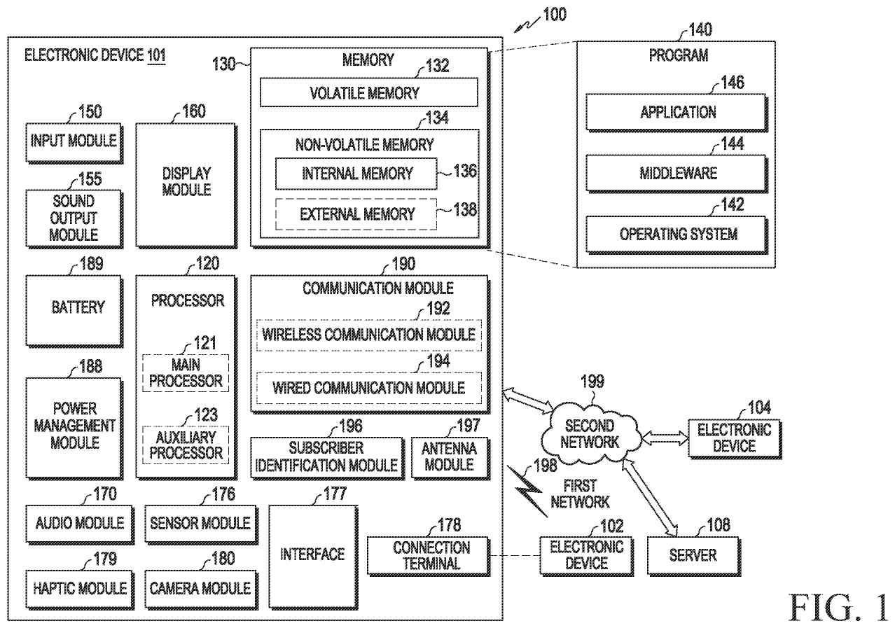

FIG. 1 is a block diagram illustrating an electronic device 101 in a network environment 100 according to various embodiments.

Referring to FIG. 1, the electronic device 101 in the network environment 100 may communicate with an electronic device 102 via a first network 198 (e.g., a short-range wireless communication network), or an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In some embodiments, at least one of the components (e.g., the connecting terminal 178) may be omitted from the electronic device 101, or one or more other components may be added in the electronic device 101. In some embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to one embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control, for example, at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active (e.g., executing an application) state. According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or an external electronic device (e.g., an electronic device 102 (e.g., a speaker or a headphone)) directly or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, an HDMI connector, a USB connector, an SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to one embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device 104 via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify or authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (cMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element composed of a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, an RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the external electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

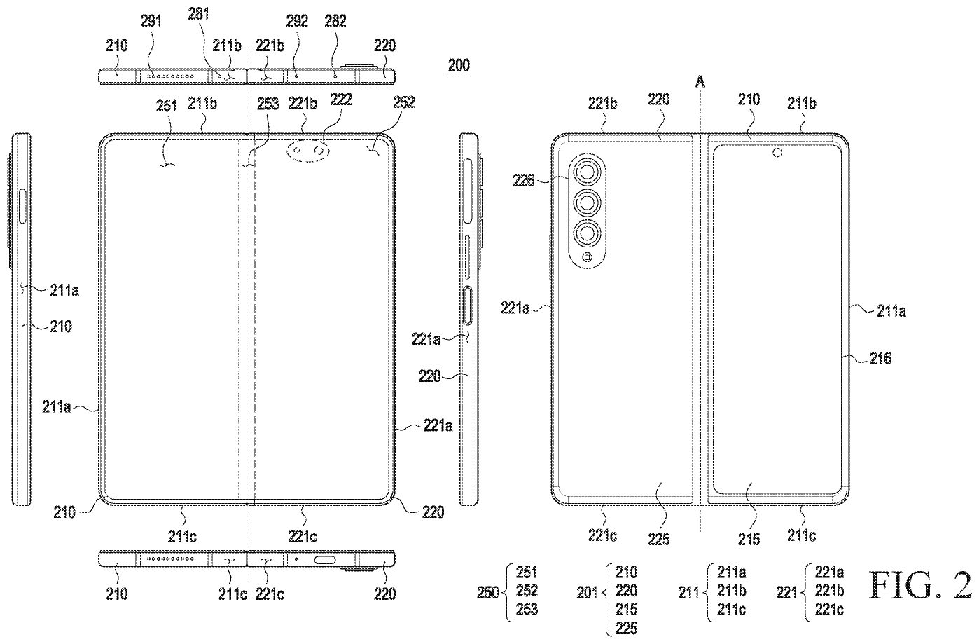

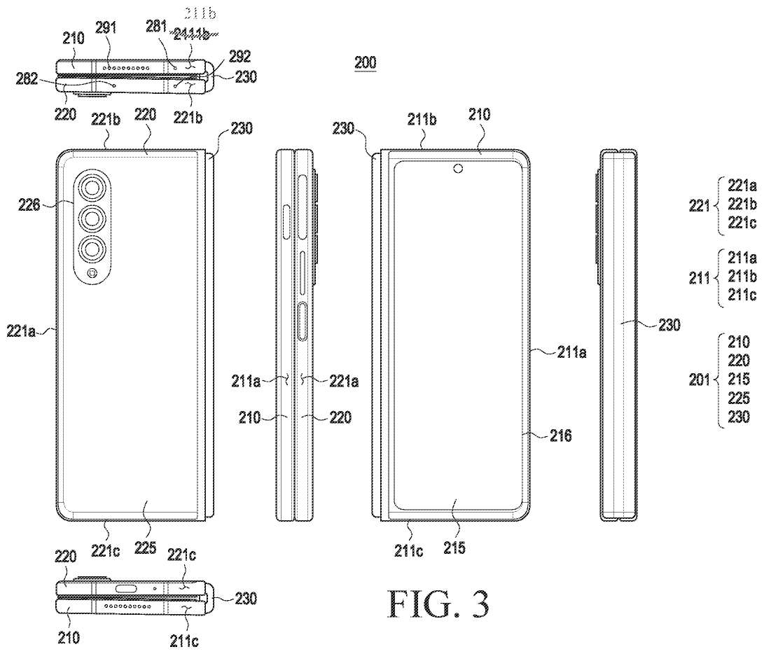

FIG. 2 is a view illustrating an unfolded state of an electronic device 200, according to an embodiment. FIG. 3 is a view illustrating a folded state of an electronic device 200, according to an embodiment. An electronic device 200 may be a foldable or a bendable electronic device as an example of the electronic device 101 illustrated in FIG. 1.

Referring to FIG. 2 and FIG. 3, in an embodiment, the electronic device 200 may include a foldable housing 201 and a flexible or a foldable display 250 (hereinafter, abbreviated as a “display” 250) (e.g., the display device 160 of FIG. 1) disposed in a space formed by the foldable housing 201. According to an embodiment, a surface (or a surface in which the display 250 is seen from the outside of the electronic device 200), on which the display 250 is disposed, may be defined as the front surface of the electronic device 200. In addition, a surface opposite to the front surface may be defined as the rear surface of the electronic device 200. In addition, a surface surrounding a space between the front surface and the rear surface may be defined as the side surface of the electronic device 200.

According to an embodiment, the foldable housing 201 may include a first housing structure 210, a second housing structure 220 including a sensor area 222, a first rear cover 215, a second rear cover 225, and a hinge structure 230. Here, the hinge structure 230 may include a hinge cover configured to cover a foldable portion of the foldable housing 201. The foldable housing 201 of the electronic device 200 may not be limited to the shape and the combination illustrated in FIG. 2 and FIG. 3, and may be implemented by other shapes or combinations and/or couplings of other components. For example, in another embodiment, the first housing structure 210 and the first rear cover 215 may be integrally formed, and the second housing structure 220 and the second rear cover 225 may be integrally formed.

According to an embodiment, an illuminance sensor (e.g., not shown) and an image sensor (not shown) may be arranged in the sensor area 212. The illuminance sensor may detect the amount of light around the electronic device 200, and the image sensor may convert light incident through a camera lens into a digital signal. The illuminance sensor and the image sensor may be visually exposed on the flexible display 250. According to another embodiment, the illuminance sensor and the image sensor may not be visually exposed. For example, a camera may include an under-display camera (UDC). Pixels in an area of the flexible display 250 corresponding to the position of the UDC may be configured differently from pixels in other areas so that the image sensor and/or the camera are not visually exposed.

According to an embodiment, the first housing structure 210 may be connected to the hinge structure 230 and may include a first surface configured to face a first direction, and a second surface configured to face a second direction opposite to the first direction. The second housing structure 220 may be connected to the hinge structure 230 and may include a third surface configured to face a third direction, and a fourth surface configured to face a fourth direction opposite to the third direction. The second housing structure 220 may rotate with respect to the first housing structure 210 around the hinge structure 230. The electronic device 200 may be changed to a folded state (status) or an unfolded state (status).

According to an embodiment, the first housing structure 210, between the first surface and the second surface, may include a first side surface 211a disposed to be parallel to and spaced apart from a folding axis A of the hinge structure 230, and the second housing structure 220, between the third surface and the fourth surface, may include a second side surface 221a disposed to be parallel to and spaced apart from the folding axis A of the hinge structure 230. In addition, the first housing structure 210 may include a third side surface 211b which is perpendicular to the first side surface 211a and has one end connected to the first side surface 211a and the other end connected to the hinge structure 230, and a fourth side surface 211c which is perpendicular to the first side surface 211a, has one end connected to the first side surface 211a and the other end connected to the hinge structure 230, and is spaced apart in a direction parallel to the third side surface 211b. The second housing structure 220 may include a fifth side surface 221b which is perpendicular to the second side surface 221a and has one end connected to the second side surface 221a and the other end connected to the hinge structure 230, and a sixth side surface 221c which is perpendicular to the second side surface 221a, has one end connected to the second side surface 221a and the other end connected to the hinge structure 230, and is spaced apart in a direction parallel to the fifth side surface 221b. When the second housing structure 220 is folded with respect to the first housing structure 210 around the hinge structure 230, the first side surface 211a may be close to the second side surface 221a, and when the second housing structure 220 is unfolded with respect to the first housing structure 210 around the hinge structure 230, the first side surface 211a and the second side surface 221a may be far away from each other.

According to an embodiment, when the electronic device 200 is in a fully folded state, the first surface may face the third surface, and when being in a fully unfolded state, the third direction may be identical to the first direction. When being in a fully unfolded state, the distance between the first side surface 211a and the second side surface 221a may be the farthest.

According to an embodiment, the first housing structure 210 and the second housing structure 220 may be respectively arranged at both sides with reference to the folding axis A, and may have an overall symmetrical shape with respect to the folding axis A. As will be described below, the angle formed by or the distances between the first housing structure 210 and the second housing structure 220 may become different depending on whether the electronic device 200 is in an unfolded state (status), a folded state (status), or a partially unfolded (or partially folded) intermediate state (status).

According to an embodiment, as illustrated in FIG. 2, the first housing structure 210 and the second housing structure 220 may together form a recess configured to accommodate the display 250. According to an embodiment, at least a part of the first housing structure 210 and the second housing structure 220 may be formed of a metal material or a non-metal material having rigidity of a size selected to support the display 250. The at least a part formed of the metal material may provide a ground plane of the electronic device 200, and may be electrically connected to a ground line formed on a printed circuit board disposed inside the foldable housing 201.

According to an embodiment, a protective member (not shown) may be disposed on the perimeter of the flexible display 250. The protective member may be integrally formed with the side surface of the foldable housing 201 or may be formed as a separate structure. The flexible display 250 may not be adhered to the side surface of the foldable housing 201 and/or the protective member. A gap may be formed between the flexible display 250 and the protective member. The protective member may be configured to cover the internal configuration of the electronic device 200 from the outside, or to protect the internal configuration of the electronic device 200 from external impact. According to an embodiment, the protective member may be configured to cover a wire mounted to the flexible display 250 from the outside, or to protect the wire from external impact.

According to an embodiment, the first rear cover 215 may be disposed at a side of the folding axis A on the rear surface of the electronic device 200 and for example, may have a substantially rectangular edge (periphery), and the edge thereof may be surrounded by the first housing structure 210. Similarly, the second rear cover 225 may be disposed at the other side of the folding axis A on the rear surface of the electronic device 200, and the edge thereof may be surrounded by the second housing structure 220.

According to an embodiment, the first rear cover 215 and the second rear cover 225 may have a substantially symmetrical shape with reference to the folding axis A. However, the first rear cover 215 and the second rear cover 225 may not necessarily have a mutually symmetrical shape, and in another embodiment, the electronic device 200 may include the first rear cover 215 and the second rear cover 225 having various shapes. In another embodiment, the first rear cover 215 may be integrally formed with the first housing structure 210, and the second rear cover 225 may be integrally formed with the second housing structure 220.

According to an embodiment, the first rear cover 215, the second rear cover 225, the first housing structure 210, and the second housing structure 220 may form a space in which various components (e.g., a printed circuit board or a battery) of the electronic device 200 can be arranged. According to an embodiment, one or more components may be arranged or may be visually exposed on the rear surface of the electronic device 200. For example, at least a part of a sub display may be visually exposed through a first rear area 216 of the first rear cover 215. In another embodiment, one or more components or sensors may be visually exposed through a second rear area 226 of the second rear cover 225. In an embodiment, the sensor may include a proximity sensor and/or a rear camera.

According to an embodiment, a front camera exposed on the front surface of the electronic device 200 or the rear camera exposed through the second rear area 226 of the second rear cover 225 may include one lens or multiple lenses, an image sensor, and/or an image signal processor. For example, a flash may include a light-emitting diode or a xenon lamp. In some embodiments, two or more lenses (an infrared camera, a wide-angle lens, and a telephoto lens) and image sensors may be arranged on one surface of the electronic device 200.

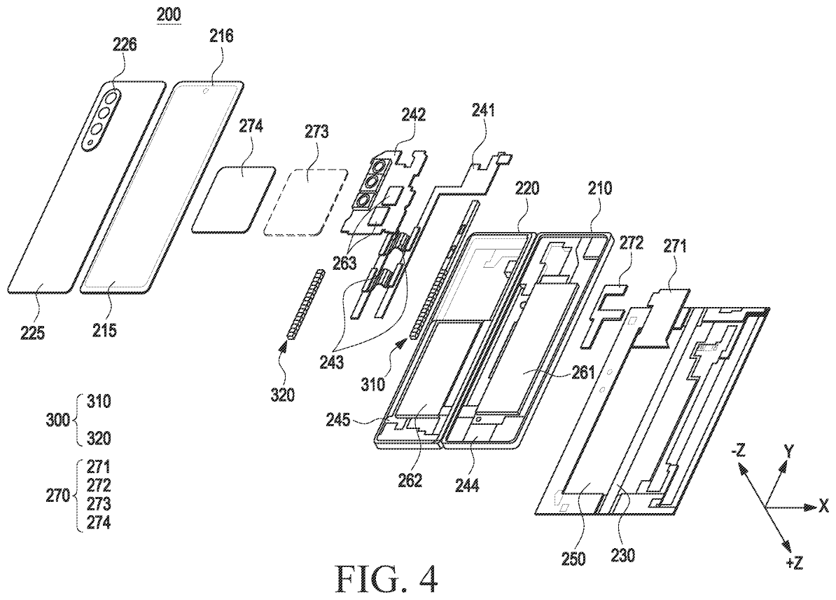

Referring to FIG. 3, a hinge cover (e.g., the hinge cover 232 of FIG. 4) included in the hinge structure 230 may be disposed between the first housing structure 210 and the second housing structure 220, and may be configured to cover an internal component (e.g., the hinge plate 231). According to an embodiment, the hinge structure 230 may be configured to be covered by a part of the first housing structure 210 and the second housing structure 220 or to be exposed to the outside, according to a state (an unfolded state (status), an intermediate state (status), or a folded state (status)) of the electronic device 200.

According to an embodiment, as illustrated in FIG. 2, when the electronic device 200 is in an unfolded state (e.g., a fully unfolded state (status)), the hinge structure 230 may be covered by the first housing structure 210 and the second housing structure 220 not to be exposed. As another example, as illustrated in FIG. 3, when the electronic device 200 is in a folded state (e.g., a fully folded state (status)), the hinge structure 230 may be exposed to the outside, between the first housing structure 210 and the second housing structure 220. As another example, when the first housing structure 210 and the second housing structure 220 are in an intermediate state (status) which is folded with a certain angle, the hinge structure 230 may be partially exposed to the outside, between the first housing structure 210 and the second housing structure 220. However, in an embodiment, the exposed area may be smaller than that in the fully folded state. In an embodiment, the hinge structure 230 may include a curved-surface.

According to an embodiment, the display 250 may be disposed in a space formed by the foldable housing 201. For example, the display 250 may be seated in a recess formed by the foldable housing 201 and may be seen from the outside through the front surface of the electronic device 200. For example, the display 250 may be configured to form most of the front surface of the electronic device 200. Accordingly, the front surface of the electronic device 200 may include the display 250, and a partial area of the first housing structure 210 and a partial area of the second housing structure 220, which are adjacent to the display 250. In addition, the rear surface of the electronic device 200 may include the first rear cover 215, a partial area of the first housing structure 210 adjacent to the first rear cover 215, the second rear cover 225, and a partial area of the second housing structure 220 adjacent to the second rear cover 225.

According to an embodiment, the display 250 may mean a display at least a partial area of which can be deformed into a flat-surface or a curved-surface. According to an embodiment, the display 250 may include a folding area 253, a first area 251 disposed at a side (e.g., the left side of the folding area 253 illustrated in FIG. 2) with reference to the folding area 253, and a second area 252 disposed at the other side (e.g., the right side of the folding area 253 illustrated in FIG. 2).

However, in an embodiment, the division of the area of the display 250 illustrated in FIG. 2 may be exemplary, and the display 250 may be divided into multiple (e.g., four or more, or two) areas according to a structure or a function thereof. For example, in the embodiment illustrated in FIG. 2, the area of the display 200 may be divided by a folding area 203 extending parallel to the folding axis A, but in another embodiment, the area of the display 200 may be divided with reference to another folding axis (e.g., a folding axis parallel to the width direction of the electronic device).

According to an embodiment, the display 250 may be coupled to or disposed adjacent to a touch panel provided with a touch sensing circuit and a pressure sensor capable of measuring the intensity (pressure) of a touch. For example, the display 250 may be an example of a touch panel, and may be coupled to or disposed adjacent to a touch panel configured to detect an electromagnetic resonance (EMR) type stylus pen.

According to an embodiment, the first area 251 and the second area 252 may have an overall symmetrical shape with reference to the folding area 253.

Hereinafter, the operation of the first housing structure 210 and the second housing structure 220 and each area of the display 250 according to a state (e.g., a folded state (status), an unfolded state (status), or an intermediate state (status)) of the electronic device 200 will be described, according to an embodiment.

According to an embodiment, when the electronic device 200 is in an unfolded state (status) (e.g., FIG. 2), the first housing structure 210 and the second housing structure 220 may form an angle of about 180 degrees and may be arranged to face the same direction. The surface of the first area 251 and the surface of the second area 252 of the display 250 may form about 180 degrees each other, and may face the same direction (e.g., the front surface direction of the electronic device). The folding area 253 may form the same flat surface as the first area 251 and the second area 252.

According to an embodiment, when the electronic device 200 is in a folded state (status) (e.g., FIG. 3), the first housing structure 210 and the second housing structure 220 may be arranged to face each other. The surface of the first area 251 and the surface of the second area 252 of the display 250 may form a narrow angle (e.g., an angle between 0 degrees and 10 degrees) and thus may face each other. At least a part of the folding area 253 may be formed as a curved-surface having a predetermined curvature.

According to an embodiment, when the electronic device 200 is in an intermediate state (status), the first housing structure 210 and the second housing structure 220 may be arranged to have a certain angle. The surface of the first area 251 and the surface of the second area 252 of the display 250 may form an angle larger than that of a folded state and smaller than that of an unfolded state. At least a part of the folding area 253 may be formed as a curved-surface having a predetermined curvature, and in this case, the curvature may be smaller than that of a folded state (status).

In an embodiment and referring to FIG. 2 and FIG. 3, a first vent hole 281, a second vent hole 282, first electrical component holes 291, and a second electrical component hole 292 may be formed through the electronic device 200.

According to an embodiment, the first vent hole 281 and the first electrical component holes 291 may be formed through the upper side surface of the first housing structure 210. According to an embodiment, the first vent hole 281 may be formed closer to the hinge structure 230 than the first electrical component holes 291.

According to an embodiment, the second vent hole 282 and the second electrical component hole 290 may be formed through the upper side surface of the second housing structure 220. According to an embodiment, the second electrical component hole 292 may be formed closer to the hinge structure 230 than the second vent hole 282.

According to an embodiment, in a state in which the second housing structure 220 is folded with respect to the first housing structure 210, the second electrical component hole 292 formed through the second housing structure 220 may be disposed on the same line as the first vent hole 281 formed through the first housing structure 210 of the electronic device 200 in a folded state.

According to an embodiment, in a state in which the second housing structure 220 is folded with respect to the first housing structure 210, the second vent hole 282 formed through the second housing structure 220 may be disposed on the same line as any one of the first electrical component holes 291 formed through the first housing structure 210 of the electronic device 200 in a folded state.

In an embodiment, the first electrical component holes 291 and the second vent hole 282, and the first vent hole 281 and the second electrical component hole 292 may be arranged on the same line, and thus a user may feel an aesthetic feeling from the arrangement of each configuration thereof.

According to an embodiment, the first vent hole 281 and the second vent hole 282 may be formed to communicate with a closed space which is formed by a first waterproof member to fourth waterproof member (e.g., the first waterproof 271 to the fourth waterproof member 274 of FIG. 4) arranged on the front surface and rear surface of the foldable housing 201, which is to be described later. The first vent hole 281 and the second vent hole 282 may be configured to allow gas to flow therethrough, and to block the inflow of liquid.

According to an embodiment, the positions of the second electrical component hole 292 and the second vent hole 282 may be changed, and the positions of the first electrical component holes 291 and the first vent hole 281 may also be configured to be changed.

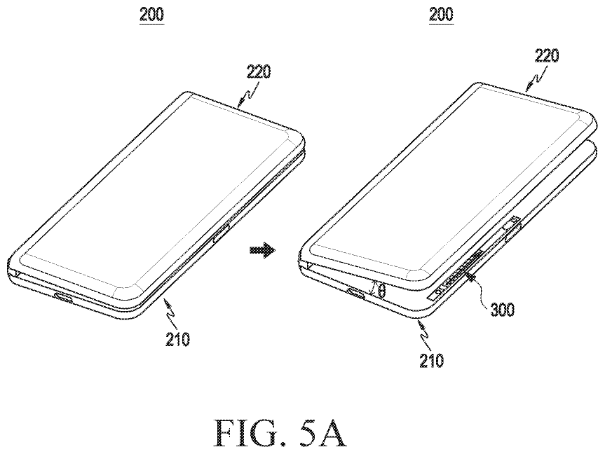

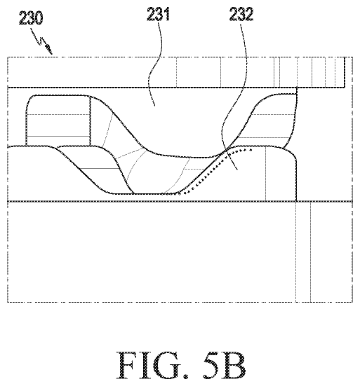

FIG. 4 is an exploded perspective view of an electronic device 200, according to an embodiment. FIG. 5A is a perspective view illustrating an electronic device 200 opened from a closed state to an open state, according to an embodiment. FIG. 5B is a view illustrating the shape of a cam included in the hinge structure 230, according to an embodiment.

In an embodiment, the views below FIG. 4 illustrate a spatial coordinate system defined by the X-axis, the Y-axis, and the Z-axis which are orthogonal to each other. Here, the X-axis may indicate the width direction of the electronic device, the Y-axis may indicate the longitudinal direction of the electronic device, and the Z-axis may indicate the height (or thickness) direction of the electronic device. In describing an embodiment, a “first direction (or third direction)” may mean a direction parallel to the +Z-axis, and a “second direction (or fourth direction)” may mean a direction parallel to the −Z-axis.

In describing the elements of the electronic device 200 illustrated in FIG. 4, descriptions for elements described above through FIG. 2 and FIG. 3 will be omitted within a range overlapping with the above descriptions.

According to an embodiment, the electronic device 200 may include various electronic components arranged in the inner space or the outer space of the first housing structure 210 and the second housing structure 220. For example, the various electronic components may include a processor 263 (e.g., the processor 120 of FIG. 1), a memory (e.g., the memory 130 of FIG. 1), an input module (e.g., the input module 150 of FIG. 1), a sound output module (e.g., the sound output module 155 of FIG. 1), the display 250 (e.g., the display module 160 of FIG. 1), an audio module (e.g., the audio module 170 of FIG. 1), a sensor (e.g., the sensor module 176 of FIG. 1), an interface (e.g., the interface 177 of FIG. 1), a connection terminal (e.g., the connection terminal 178 of FIG. 1), a haptic module (e.g., the haptic module 179 of FIG. 1), a camera module (e.g., the camera module 180 of FIG. 1), a power management module (e.g., the power management module 188 of FIG. 1), batteries 261 and 262 (e.g., the battery 189 of the FIG. 1), a communication module (e.g., the communication module 190 of FIG. 1), a subscriber identification module (e.g., the subscriber identification module 196 of FIG. 1), or an antenna module (e.g., the antenna module 197 of FIG. 1), and the electronic components may be appropriately divided to be arranged in the inner space or the outer space of the first housing structure 210 and the second housing structure 220. In the electronic device 200, at least one (e.g., the connection terminal 178) of the elements may be omitted, or one or more other elements may be added. In addition, some of the elements may be integrated into one element.

According to an embodiment, the electronic device 200 may be a foldable electronic device, and may include multiple batteries for supplying, to electronic components, and storing power required for driving thereof. For example, a first battery 261 and a second battery 262 respectively arranged in the first housing structure 210 and the second housing structure 220 may be included therein.

According to an embodiment, the electronic device 200 may be a foldable electronic device, and may be provided with support members (or plates) 244 and 245 which are configured to allow components to be arranged in each of the first housing structure 210 and the second housing structure 220. Various types of electronic components and/or printed circuit boards 241 and 242 may be arranged on the support members 244 and 245. For example, a first support member (or a first plate) 244 and a first printed circuit board 241 may be arranged in the first housing structure 210, and a second support member (or second plate) 245 and a second printed circuit board 242 may be arranged in the second housing structure 220. For example, the second printed circuit board 242 may be a main printed circuit board on which the processor 263 is disposed. Signals of the processor 263 configured to implement various functions and operations of the electronic device 200 may be delivered to electronic components through various types of conductive lines 243 and/or connection members (connectors) formed on the printed circuit boards 241 and 242.

According to an embodiment, the flexible display 250 may include a display panel (not shown). In an embodiment, the first support member 243 and the second support member 244 may be arranged between the display panel, the first printed circuit board 241, and the second printed circuit board 242. The hinge structure 230 may be disposed between the first support member 243 and the second support member 244.

According to an embodiment, the hinge structure 230 may include a hinge plate and a hinge cover. The hinge cover may be configured to cover the hinge plate disposed inside the hinge structure 230 and hinge modules coupled thereto.

According to an embodiment, the first housing structure 210 and the second housing structure 220 may be assembled to each other to be coupled to both sides of the hinge structure 230 when the flexible display 250 is coupled to the first support member 243 and the second support member 244. For example, the first housing structure 210 may be coupled by sliding from one side of the hinge structure 230, and the second housing structure 220 may be coupled by sliding from the other side of the hinge structure 230.

According to an embodiment, various members may be arranged inside the electronic device 200. According to an embodiment, the various members may be arranged in the first housing structure 210 and/or between the first support member 243 and the flexible display 250. According to an embodiment, the various members may be arranged in the second housing structure 220 and/or between the second support member 244 and the flexible display 250. According to another embodiment, the various members may be arranged on first printed circuit board 241 and/or between the first housing structure 210 and the first rear cover 215, and may be arranged on the second printed circuit board 242 and/or between the second housing structure 220 and the second rear cover 225. According to an embodiment, the various members may include a waterproof member 270, an adhesive member, a support member, and a buffer member.

According to an embodiment, FIG. 4 illustrates the multiple waterproof members 270 as the various members. For example, the electronic device may include a first waterproof member 271, a second waterproof member 272, a third waterproof member 273, and a fourth waterproof member 274.

According to an embodiment, the first waterproof member 271 may be disposed between the first support member 243 of the first housing structure 210 and a first area (e.g., the first area 251 of FIG. 2) of the flexible display 250. According to an embodiment, the first waterproof member 271 may be formed as a waterproof tape. The first waterproof member 271 may be adhered to the first housing structure and/or the first support member 243, and may be adhered to the flexible display 250. The first waterproof member 271 may be formed as a closed curve. The first waterproof member 271 formed as a closed curve may include at least one area. As the first waterproof member 271 is formed as a waterproof tape and includes at least one area formed as a closed curve, it may be possible to prevent liquid from flowing into the inside of the closed curve from the outside of the closed curve of the first waterproof member 271.

According to an embodiment, the second waterproof member 272 may be disposed between the second support member 244 of the second housing structure 220 and a second area (e.g., the second area 252 of FIG. 2) of the flexible display 250. According to an embodiment, the second waterproof member 272 may be formed as a waterproof tape. The second waterproof member 272 may be adhered to the second housing structure 220 and/or the second support member 244, and may be adhered to the flexible display 250. The second waterproof member 272 may be formed as a closed curve. The second waterproof member 272 formed as a closed curve may include at least one area. As the second waterproof member 272 is formed as a waterproof tape and includes at least one area formed as a closed curve, it may be possible to prevent liquid from flowing into the inside of the closed curve from the outside of the closed curve of the second waterproof member 272.

According to an embodiment, the first waterproof member 271 and the second waterproof member 272 may be arranged not to be in contact with the hinge structure 230. According to an embodiment, the third waterproof member 273 may be disposed between the first housing structure 210 and the first rear cover 215. According to an embodiment, the third waterproof member 273 may be formed as a bond and/or a waterproof tape. The third waterproof member 273 may be adhered to the first housing structure 210, and may be adhered to the first rear cover 215. The third waterproof member 273 may be formed as a closed curve. The third waterproof member 273 formed as a closed curve may include at least one area. As the third waterproof member 273 is formed as a waterproof tape and includes at least one area formed as a closed curve, it may be possible to prevent liquid from flowing into the inside of the closed curve from the outside of the closed curve of the third waterproof member 273.

According to an embodiment, the fourth waterproof member 274 may be disposed between the second housing structure 220 and the second rear cover 225. According to an embodiment, the fourth waterproof member 274 may be formed as a waterproof tape. The fourth waterproof member 274 may be adhered to the second housing structure the 220, and may be adhered to at least a part of the second rear cover 225. The fourth waterproof member 274 may be formed as a closed curve. The fourth waterproof member 274 formed as a closed curve may include at least one area. As the fourth waterproof member 274 is formed as a bond and includes at least one area formed as a closed curve, it may be possible to prevent liquid from flowing into the inside of the closed curve from the outside of the closed curve of the fourth waterproof member 274.

In an embodiment, as the waterproof member 270 is disposed inside the electronic device 200, it is possible to prevent liquid from flowing into the inside of the electronic device 200 from the outside of the electronic device 200.

In addition, in an embodiment, at least one of various members (e.g., an adhesive member, a support member, and/or a buffer member) may be arranged inside the electronic device 200.

In an embodiment and referring to FIG. 4 and FIG. 5A together, in a foldable electronic device which is very frequently opened or closed and has a foldable display, an automatic opening module 300 may be provided to provide user convenience.

According to an embodiment, the automatic opening module 300 may include a first magnetic body part 310 which is disposed at a position adjacent to a side edge of the first housing structure 210 and includes magnetic bodies arranged along the longitudinal direction (e.g., the Y-axis direction) of the first housing structure 210, and a second magnetic body part 320 which is disposed at a position adjacent to a side edge of the second housing structure 220 and a position corresponding to the first magnetic body part 310 and includes magnetic bodies arranged along the longitudinal direction (e.g., Y-axis direction) of the second housing structure 220.

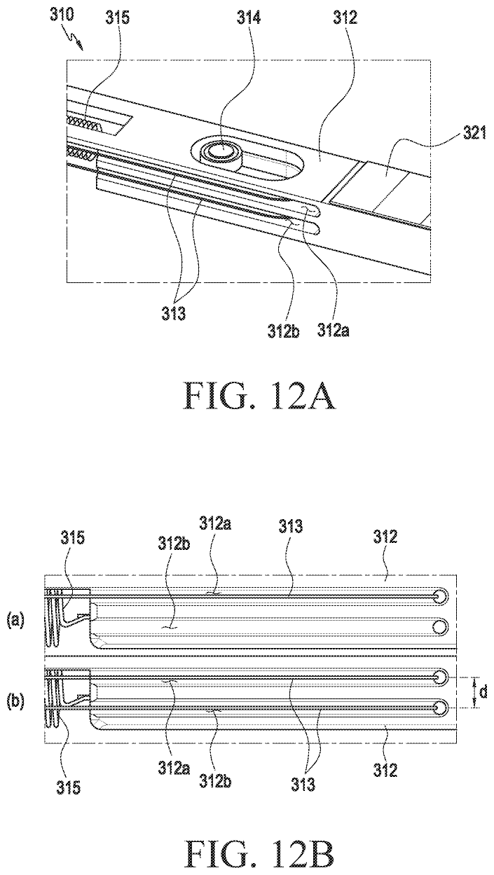

In an embodiment, at least one of the first magnetic body part 310 and the second magnetic body part 320 may be formed as a movable magnetic body module including a shape memory alloy (SMA) member capable of being deformed or restored along the longitudinal direction (e.g., the Y-axis direction) of the electronic device. For example, as illustrated in FIG. 4, the first magnetic body part 310 may be formed as a movable magnetic body module. In the case, as illustrated in FIG. 4, the second magnetic body part 320 may be provided as a stationary magnetic body, or as will be described later through FIG. 12, the second magnetic body part 320 may also be formed as a movable magnetic body module.

According to an embodiment, the first magnetic body part 310, in the first housing structure 210, may be disposed at a position adjacent to a first side surface (e.g., the first side surface 211a of FIG. 2) which is parallel to and spaced apart from the hinge structure 230, for example, the space between the first battery 261 and the first housing structure 210. In addition, the second magnetic body part 320, in the second housing structure 220, may be disposed at a position adjacent to a second side surface (e.g., the second side surface 221a of FIG. 2) which is parallel to and spaced apart from the hinge structure 230, for example, the space between the second battery 262 and the second housing structure 220.

In an embodiment and referring to FIG. 5A and FIG. 5B together, when the electronic device is changed from a closed state (e.g., the left view of FIG. 5A) to an open state (e.g., the right view of FIG. 5A), the electronic device 200 may be configured to use the automatic opening module 300 including a shape memory alloy member, and thus may be configured to implement an easy-opening operation of automatically opening the first housing structure 210 and the second housing structure 220 of the electronic device 200 by a predetermined angle θ (or a predetermined distance), thereby improving user convenience. According to an embodiment, the predetermined angle θ may be an angle designated by the hinge structure 230 provided with cams 231 and 232 which have surfaces facing each other, each of the surfaces having a valley portion and a mounting portion which correspond to each other. Referring to FIG. 5A, when the electronic device 200 is in a closed state, the first magnetic body part 310 and the second magnetic body part 320 may be configured to generate attractive force to each other, and when the electronic device 200 is changed into an open state, the automatic opening module 300 including the shape memory alloy may be used to move at least one magnetic body array in one direction, thereby removing the attractive force between the first magnetic body part 310 and the second magnetic body part 320. In the case, the angle between the first housing structure 210 and the second housing structure 220 of the electronic device 200 may be opened by the predetermined angle θ by driving force of the hinge structure 230 and/or repulsive force of the flexible display 250.

According to an embodiment, when being changed into an open state, the automatic opening module 300 including the shape memory alloy member may be used to change the polarity of the magnetic body array, and thus attractive force between the first magnetic body part 310 and the second magnetic body part 320 is removed and repulsive force is generated between the first magnetic body part 310 and the second magnetic body part 320, so that the housing structures can be opened by an angle greater than the predetermined angle θ.

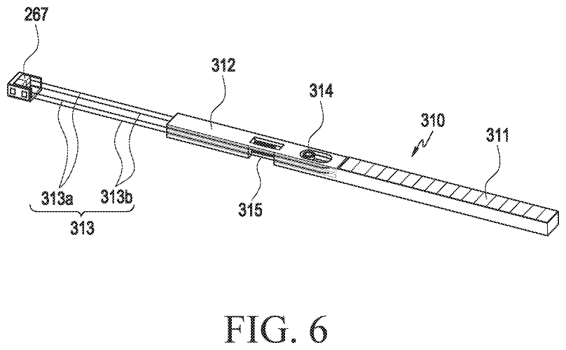

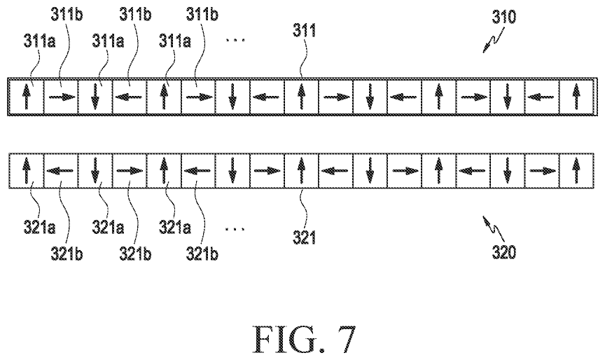

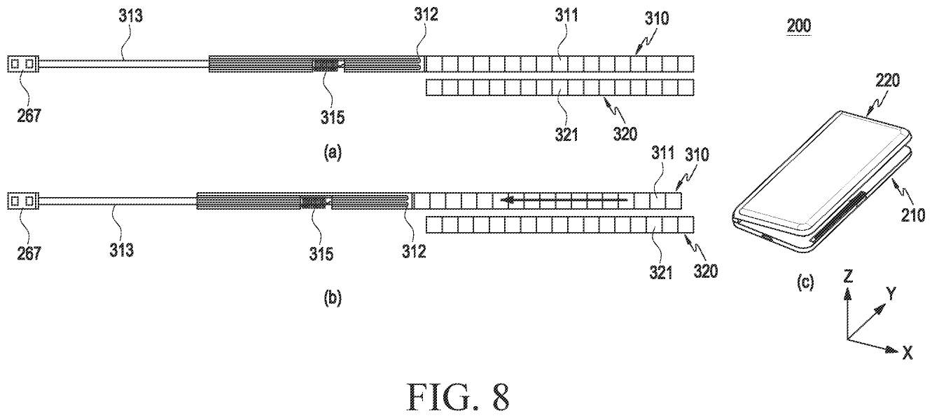

FIG. 6 is a view illustrating a movable magnetic body module, according to an embodiment. FIG. 7 is a view illustrating a magnetic body array having a Halbach arrangement, according to an embodiment. FIG. 8A to FIG. 8C are views showing an operation of an automatic opening module before feeding and after feeding, according to an embodiment.

According to an embodiment and referring to FIG. 6 to FIG. 8C together with the drawings described above, the automatic opening module 300 included in the electronic device according to an embodiment will be described in more detail.

In an embodiment, and as describe above through FIG. 4, at least one of the first magnetic body part 310 and the second magnetic body part 320 may be formed as a movable magnetic body module including a shape memory alloy member capable of being deformed or restored along the longitudinal direction (e.g., the Y-axis direction) of the electronic device. For example, when the first magnetic body part 310 is formed as a movable magnetic body module, the second magnetic body part 320 may be formed as a stationary magnetic body, and on the contrary thereto, when the first magnetic body part 310 is formed as a stationary magnetic body, the second magnetic body part 320 may be formed as a movable magnetic body module. As another example, both the first magnetic body part 310 and the second magnetic body part 320 may be formed as a movable magnetic body module.

In the following drawings (e.g., FIG. 6 to FIG. 9), the structure and the operation method of the automatic opening module 300 will be described according to an embodiment in which the first magnetic body part 310 is formed as a movable magnetic body module and the second magnetic body part 320 is formed as a stationary magnetic body. Hereinafter, the first magnetic body part 310 may be referred to as a “movable magnetic body module 310”, and the second magnetic body part 320 may be referred to as a “stationary magnetic body 320”.

According to an embodiment, the movable magnetic body module 310 may include a magnetic body array 311, a support body 312 provided at a side of the magnetic body array 311, a shape memory alloy member capable of being contracted or relaxed in a state of being at least partially supported to the support body 312, and a spring 315 configured to restore the movable magnetic body module.

In an embodiment, the magnetic body array 311 of the movable magnetic body module 310 may be formed by multiple permanent magnets which are successively connected to each other in one direction (e.g., the longitudinal direction (e.g., the Y-axis direction) of the electronic device 200), and the multiple permanent magnets may be arranged such that the directions of the magnetic fields, which are formed between the magnets adjacent to each other, are different. In this case, the number of the arrayed magnets may not be limited. According to an embodiment, the stationary magnetic body 320 may also include a magnetic body array 321 corresponding to the magnetic body array 311 of the movable magnetic body module 310. The fact that the magnetic body array 321 of the stationary magnetic body 320 corresponds to the magnetic body array 311 of the movable magnetic body module 310 may mean that the numbers of the successively connected permanent magnets are the same and the magnetic body arrays are formed to have the same total length.

In an embodiment and referring to FIG. 7, the magnetic body array 311 may be formed such that a series of permanent magnets form a Halbach arrangement in which a weak magnetic field is generated in one direction and a strong magnetic field is generated in the other direction. According to an embodiment, when the magnetic body array 311 (hereinafter, may be referred to as a “first magnetic body array 311”) of the movable magnetic body module 310 forms a Halbach arrangement, the magnetic body array 321 (hereinafter, may be referred to as a “second magnetic body array 321”) of the stationary magnetic body 320 may also form a Halbach arrangement. For example, referring to FIG. 7, the first magnetic body array 311 may include multiple first poles 311a configured to form a magnetic field in a direction perpendicular to the longitudinal direction of the first magnetic body array 311 and multiple second poles 311b configured to form a magnetic field in a direction parallel to the longitudinal direction thereof, and the multiple first poles 311a and the multiple second poles 311b may be arranged to alternately generate a strong magnetic field and generate also a strong magnetic field toward one surface (e.g., the downward direction of FIG. 7) of the first magnetic body array 311. The second magnetic body array 321 may include multiple third poles 321a configured to form a magnetic field in a direction perpendicular to the longitudinal direction of the second magnetic body array 321 and multiple fourth poles 321b configured to form a magnetic field in a direction parallel to the longitudinal direction thereof, and the multiple third poles 321a and the multiple fourth poles 321b may be arranged to alternately generate a strong magnetic field and generate also a strong magnetic field toward one side (e.g., the upward direction of FIG. 7) of the second magnetic body array 321. As illustrated in FIG. 7, in a state where one ends and the other ends of the first magnetic body array 311 and the second magnetic body array 321 are aligned with each other and magnets of thereof are arranged to face one to one, when the first poles 311a of the first magnetic body array 311 and the third poles 321a of the second magnetic body array 321 are directed in the same direction, and the second poles 311b of the first magnetic body array 311 and the fourth poles 321b of the second magnetic body array 321 are directed in different directions, attractive force may be applied between the magnetic body arrays 311 and 321. As described above, as the magnetic body arrays 311 and 321 are formed in a Halbach arrangement, the space (or area), which is occupied by the magnetic body arrays 311 and 321 in the inner space of the electronic device 200, may be minimized, and the maximum magnetic force may be generated.

In an embodiment and referring again to FIG. 6, the support body 312 may be a portion having a long body in the same direction as the direction in which the magnetic body array 311 extends, and for example, may have a function such as a bracket for the magnetic body array 311 and the shape memory alloy member.

In an embodiment, the shape memory alloy member may have a configuration in which the arrangement of crystals thereof can be deformed according to a temperature or restored to the original shape after deformation. According to an embodiment, for example, the shape memory alloy member may include a shape memory alloy wire 313. The shape memory alloy wire 313 may be contracted or relaxed according to a temperature so that the total length thereof is changed. As illustrated in the drawings, the shape memory alloy wire 313 may be provided with multiple wires 313a and 313b. At least a part of the shape memory alloy wire 313 may be supported by the support body 312.

According to an embodiment, a part of the shape memory alloy wire 313 may be configured to surround the support body 312, and other parts thereof may be formed to be fixed to other elements (e.g., the feeder 267). Referring again to FIG. 6, the shape memory alloy wire 313 may be configured such that one end and the other end thereof are connected to other elements (e.g., the feeder 267) in a state of surrounding the support body 312. In this state, the shape memory alloy wire 313 may be contracted or relaxed according to a temperature. The shape memory alloy wire 313 may be contracted in a high-temperature environment so that the total length thereof is shortened, and may be relaxed in a low-temperature environment so that the length thereof is restored to the original length. In connection with the movable magnetic body module 310, when the shape memory alloy wire 313 contracts in a high-temperature environment, the support body 312 and the magnetic body array 311 may be moved in the direction in which the shape memory alloy wire 313 is contracted, and when the shape memory alloy wire 313 relaxes in a low-temperature environment, the support body 312 and the magnetic body array 311 may be moved in the direction in which the shape memory alloy wire 313 is relaxed.

In an embodiment, the feeder 267 may be the configuration for changing the temperature of the shape memory alloy wire 313. The feeder 267 may be a configuration connected to a power supply circuit disposed in the electronic device 200, and may be disposed in the longitudinal direction of the movable magnetic body module 310. One end and the other end of the shape memory alloy wire 313 may be fixedly connected to the feeder 267. The feeder 267 may supply power to the shape memory alloy wire so as to raise temperature of the wire.

In an embodiment, the spring 315 may be a configuration configured to allow the support body 312 and the magnetic body array 311 to be restored back to the original position thereof, and for example, when the shape memory alloy wire 313 contracts due to becoming a high-temperature, the spring may be contracted together, and when the shape memory alloy wire 313 is relaxed due to becoming a low-temperature, the spring may apply an elastic restoring force to the support body 312 and the magnetic body array 311.

According to an embodiment, the movable magnetic body module 310 may additionally include a retaining member 314. The retaining member 314 may be provided to limit a moving distance thereof when the support body 312 of the movable magnetic body module 310 moves in response to the contraction or relaxation of the shape memory alloy wire 313.

At least one of the position, number, and shape of the spring 315 and/or the retaining member 314 may be variously applied according to an embodiment.

In an embodiment and referring to FIG. 8A to FIG. 8C, FIG. 8A illustrates a movable magnetic body module 310 in a state before feeding or a restored (recovered) state after feeding, and FIG. 8B illustrates a movable magnetic body module 310 in a state in which the position thereof is moved according to the contraction of a shape memory alloy wire 313 when feeding. FIG. 8A illustrates a state in which attractive force is applied between the first magnetic body array 311 of the movable magnetic body module 310 and the second magnetic body array 321 of the stationary magnetic body 320.

In an embodiment, comparing FIG. 8A and FIG. 8B, when the feeder 267 supplies power to the shape memory alloy wire 313 so as to raise the temperature of the shape memory alloy wire 313, the shape memory alloy wire 313 may reach a critical temperature and thus may be contracted. Therefore, the support body 312 and the first magnetic body array 311 of the movable magnetic body module 310 may move in a direction (e.g., the longitudinal direction (the Y-axis direction) of the electronic device 200) by the contraction force of the shape memory alloy wire 313. As illustrated in FIG. 8B, as the movable magnetic body module 310 moves, the arrangement configured to allow attractive forces between the first magnetic body array 311 and the second magnetic body array 321 to be generated may be changed, and thus a change in magnetic force between the magnetic bodies may occur. For example, the state of magnetic force between the magnetic bodies may become a state in which attractive force between the first magnetic body array 311 and the second magnetic body array 321 is removed. In another embodiment, after attractive force between the first magnetic body array 311 and the second magnetic body array 321 is removed, the state of magnetic force between the magnetic bodies may become a state in which repulsive force is generated. As illustrated in FIG. 8C, the electronic device 200 may be opened to an open state by the change in magnetic force between the magnetic bodies.

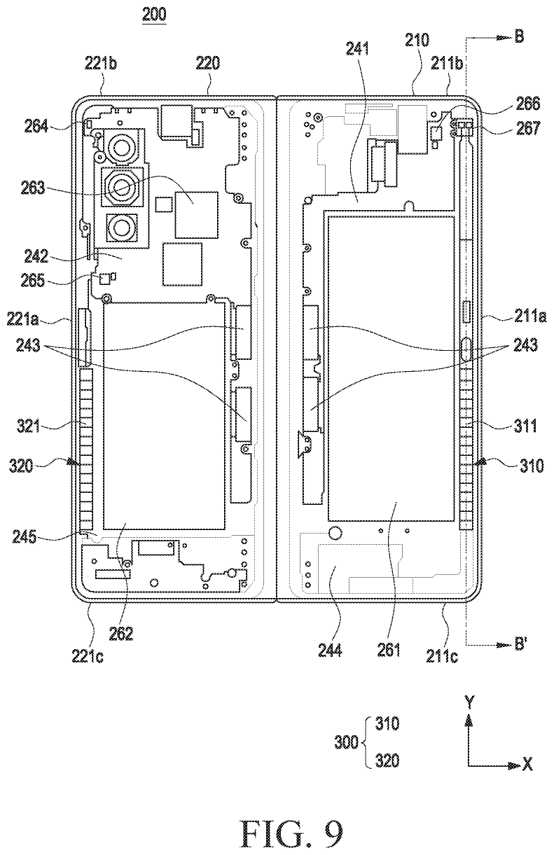

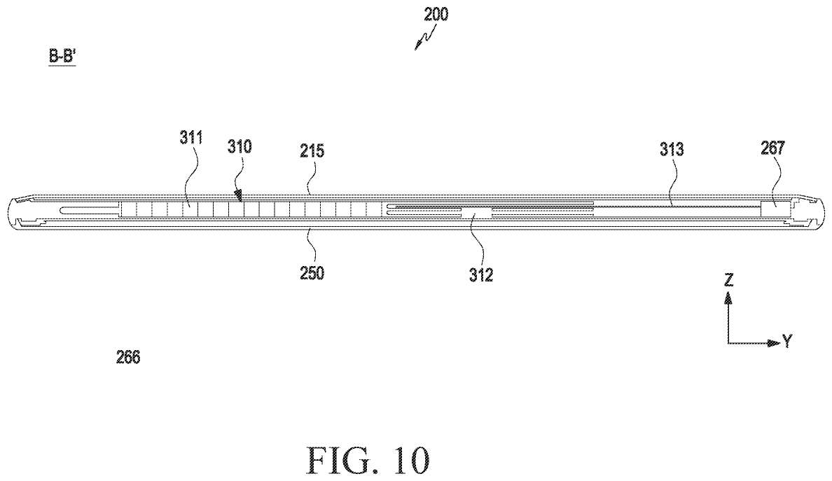

Other elements included in an electronic device 200 according to an embodiment will be described in more detail with reference to FIG. 9 and FIG. 10 together with the drawings described above.

FIG. 9 is a view illustrating an inner shape in an open state of an electronic device 200, according to an embodiment. FIG. 10 is a view illustrating a cross section taken along the direction B-B′ in the view of FIG. 9, according to an embodiment. In describing the elements illustrated in the views of FIG. 9 and FIG. 10, contents overlapping with the above-described elements will be omitted.

In an embodiment and as illustrated in FIG. 9, the movable magnetic body module 310 and the stationary magnetic body 320 may be respectively arranged on opposite edges of the first housing structure 210 and the second housing structure 220 of the electronic device 200. The second magnetic body array 321 of the stationary magnetic body 320 may be disposed at a position corresponding to the first magnetic body array 311 of the movable magnetic body module 310. According to an embodiment, the movable magnetic body module 310 may have a length longer and a volume larger than those of the stationary magnetic body 320. Therefore, it may be preferable that the movable magnetic body module 310 is disposed in consideration of the arrangement state between the other components inside the housing of the electronic device 200, but the condition may not limit the arrangement position of the movable magnetic body module 310. For example, according to the embodiment illustrated in FIG. 9, electronic components such as a key input device, a fingerprint sensor, and/or a camera module are arranged adjacent to the side surface of the second housing structure 320, and thus the stationary magnetic body 320 having a relatively small volume is disposed in the second housing structure 220 and the movable magnetic body module 310 is disposed in the first housing structure 210. However, it may not be necessarily limited thereto, and differently from what is illustrated in the drawing, the embodiment, in which the stationary magnetic body is disposed in the first housing structure 210 and the movable magnetic body module is disposed in the second housing structure 220, may be applied thereto.

In an embodiment, the movable magnetic body module 310 disposed in the first housing structure 210 may include other elements including the first magnetic body array 311, which are arranged to extend parallel to the longitudinal direction (e.g., the Y-axis direction) of the electronic device 200 (or the second housing structure 220). For example, as illustrated in FIG. 9 and FIG. 10, the magnetic body array 311, the support body 312, the shape memory alloy wire 313, and the feeder 267, which are included in the movable magnetic body module 310, may be arranged to extend parallel to the longitudinal direction (e.g., the Y-axis direction) of the electronic device 200 (or the second housing structure 220), at a position adjacent to the first side surface 211a.

In an embodiment, the electronic device 200 may include a power supply circuit. The power supply circuit may be one of the various electronic components arranged in the inner space or the outer space of the first housing structure 210 and the second housing structure 220, and according to an embodiment, may be disposed on the first printed circuit board 241 or the second printed circuit board 242.

According to an embodiment, the electronic device 200, as a power supply circuit thereof, may further include a circuit 266 configured to supply power to the shape memory alloy member and control power (hereinafter, shortly referred to as a “shape memory alloy (SMA) controller 266”). The shape memory alloy member may have a temperature as an operation mechanism thereof, and may receive power supplied therefrom to generate heat. Since Joule's heat increases as power is higher, the shape memory alloy member may be controlled through controlling power by using the SMA controller 266. The SMA controller 266 may be electrically connected to the feeder 267 to increase or lower current or voltage provided to the shape memory alloy member (e.g., the shape memory alloy wire 313), and also to adjust the time period in which current or voltage is applied thereto. According to various embodiments, the SMA controller 266 may be disposed to be spaced apart from the processor 263, and as illustrated in FIG. 9, the SMA controller and the processor may be arranged on different printed circuit boards in different housing structures. In this case, the electrical connection with the processor 263 may be implemented by a conductive line disposed on the printed circuit board and/or a connection member 243.

In an embodiment, the electronic device 200 may include various sensors (e.g., the sensor module 176 of FIG. 1) related to an automatic opening operation of the electronic device 200.

For example, the electronic device 200 may include a sensor 264 (hereinafter, referred to as an “angle sensor 264”) capable of detecting a folding angle between the first housing structure 210 and the second housing structure 220. For example, by detecting the angle between the first housing structure 210 and the second housing structure 220, which is detected by the angle sensor 264, when the first housing structure 210 and the second housing structure 220 are opened to a predetermined angle or more, the processor 263 may be configured to provide current or voltage to the shape memory alloy wire 313 through the SMA controller 266 so as to stop an automatic opening operation in progress, thereby preventing unnecessary power consumption.

In another embodiment, the electronic device 200 may include a sensor 265 (hereinafter, referred to as a “temperature sensor 265”) configured to detect a change in temperature of the electronic device or around the electronic device. The temperature of the electronic device 200 or the temperature of an environment around the electronic device 200 may be measured through the temperature sensor 265, and the processor 263, based on the temperature data, may set an optimal operating voltage to the SMA controller 266 so as to perform feeding to the shape memory alloy wire 313.

For example, in an embodiment, the following Table is a table showing the contraction and the relaxation speed of the shape memory alloy wire 313 responding to an opening operation and/or a restoring operation of the electronic device when voltages (or currents) having different magnitudes are applied thereto according to temperatures of a terminal.

TABLE 1

| | (Unit: second) | | | | | |
|---|---|---|---|---|---|---|
| Applied | Opening (Wire contraction) | | | Restoring (Wire relaxation) | | |
| voltage | 4 V(0.6 A) | 5 V(0.76 A) | 6 V(0.95 A) | 4 V(0.6 A) | 5 V(0.76 A) | 6 V(0.95 A) |
| −20° C. | 6.3 | 1.7 | 0.9 | 1.3 | 1.3 | 1.4 |
| 0° C. | 3.8 | 1.3 | 0.8 | 1.4 | 1.4 | 1.6 |
| 20° C. | 2.5 | 1.2 | 0.7 | 1.8 | 2.0 | 2.1 |
| 40° C. | 1.7 | 1.2 | 0.7 | 2.0 | 2.5 | 2.8 |
| 60° C. | 1.5 | 0.8 | 0.6 | 3.4 | 4.4 | 4.9 |

Referring to Table 1, immediacy may be enhanced by obtaining the temperature of the electronic device 200 through the temperature sensor and controlling such that the electronic device rapidly operates according to a temperature condition.

In an embodiment and referring to Table 1 above, in an opening operation, it may be identified that the contraction speed is faster as the voltage is higher. On the other hand, in a restoring operation, it may be identified that the relaxation speed is slower as the voltage is higher. Therefore, the immediacy in the speed of an opening operation and/or a restoring operation may be enhanced by applying a high-voltage thereto in the opening operation and applying a low-voltage thereto in the restoring operation. For example, the immediacy may be enhanced by differently setting voltages applied thereto according to the opening operation and the restoring operation. On the other hand, according to an embodiment, it may not be that, always, only a high-voltage is applied thereto in the case of an opening operation, it may not be that, always, only a low-voltage is applied thereto in the restoring operation, and the applied voltages may be different in consideration of a temperature condition of the electronic device 200. For example, when a voltage of about 4V is applied thereto in an approximate −20° C. environment, the opening speed is about 6.3 seconds. Therefore, it may be identified that the opening speed becomes significantly faster as the applied voltage is higher (e.g., the opening speed is about 1.7 seconds when about 5V voltage is applied, and the opening speed is about 0.9 seconds when about 6V voltage is applied). On the other hand, when a voltage of about 4V is applied thereto in an approximate 60° C. environment, the opening speed is about 1.5 seconds. Although the opening speed is slightly faster as the applied voltage is higher, it may be identified that the difference therebetween is not significant (e.g., the opening speed is about 0.8 seconds when about 5V voltage is applied, and the opening speed is about 0.6 seconds when about 6V voltage is applied). Considering the tendency, a high-voltage may be applied thereto under a low-temperature, and an average voltage may be applied thereto under a high-temperature.

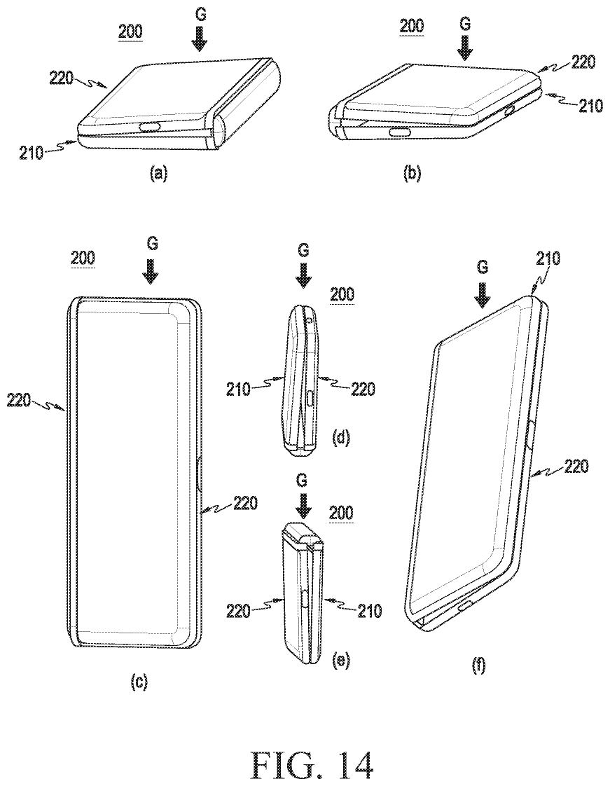

In another embodiment, although not illustrated in the drawings, the electronic device 200 may include a sensor (not shown) (hereinafter, referred to as an “acceleration sensor”) configured to detect the tilt of the electronic device 200 with respect to the direction of gravity. The horizontal, the vertical, the tile, etc. of the electronic device 200 with respect to the direction of gravity with reference to the ground may be accurately identified using the acceleration sensor, and the processor 263, based on the data, may set an optimal operating voltage to the SMA controller 266 so as to perform feeding to the shape memory alloy wire 313. An embodiment configured to detect the tilt with respect to the direction of gravity will be described later in more detail as illustrated in FIG. 14A to FIG. 14F.

According to an embodiment, the electronic device 200 may include the above-described sensors and may be configured to control current or voltage flowing through the shape memory alloy, based on the data measured by the sensors, thereby ensuring immediacy in opening and/or restoring in various temperature environments. In addition, the electronic device may be configured to perform an appropriate control according to various tilting states and folding states of the foldable electronic device, thereby reducing the opening and/or the restoring time and power consumption thereof.

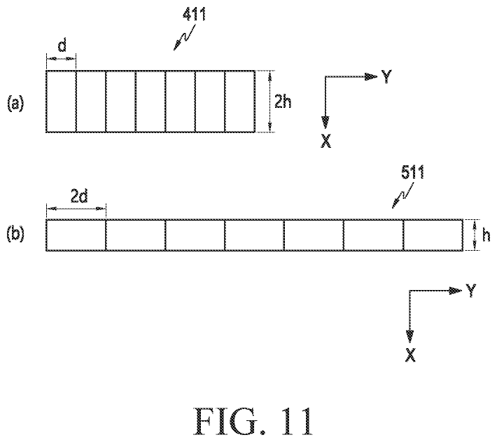

FIG. 11A is a view illustrating an array structure of a magnetic body array, according to an embodiment. FIG. 11B is a view illustrating an array structure of a magnetic body array, according to an embodiment.

In an embodiment, FIG. 11A and FIG. 11B illustrate two magnetic body arrays 411 and 511 having different dimensions. One magnetic body array 411 of the two magnetic body arrays 411 and 511 may have a length which is a length in the longitudinal direction (the Y-axis direction) of the electronic device and is formed to be relatively long, and a width which is a length in the width direction (the X-axis direction) of the electronic device and is formed to be relatively short. The other one magnetic body array 511 may have a length which is a length in the longitudinal direction (the Y-axis direction) of the electronic device and is formed to be relatively short, and a width which is a length in the width direction (the X-axis direction) of the electronic device and is formed to be relatively long. The one magnetic body array 411 may be formed by the combination of permanent magnets each having a length d and a width 2h, and the other one magnetic body array 511 may be formed by the combination of permanent magnets each having a length 2d and a width h. In this case, it may be assumed that the total area of each thereof is identical and thus each thereof provides a magnetic force having the same magnitude. When the magnetic body arrays 411 and 511 are used as the automatic opening module of the electronic device, the one magnetic body array 411 may have the short length d which allows attractive force to be removed when moving in the electronic device, but the other one magnetic body array 511 may have the length 2d which is formed relatively long and allows attractive force to be removed when moving in the electronic device. In the magnetic body array 511, it may mean that it takes more time to remove the attractive force therebetween. That is, according to the embodiment illustrated in FIG. 11A and FIG. 11B, an electronic device, which has the magnetic body array 511 used as the automatic opening module, may have an operating speed slower that the operating speed of an electronic device using the magnetic body array 411.

In an embodiment, in order to ensure immediacy, the electronic device array (e.g., the magnetic body array 411) having a length which is a length in the longitudinal direction (the Y-axis direction) of the electronic device and is formed to be relatively long and having a length which is a length in the width direction (the X-axis direction) of the electronic device and is formed to be relatively short, may be adopted as a magnetic body array according to various embodiments of the disclosure.

FIG. 12A is an enlarged view of a portion of a support body 312 included in a movable magnetic body module 310, according to an embodiment. FIG. 12B is a view showing a state in which a shape memory alloy wire 313 is seated on a support body 312, according to an embodiment.

In an embodiment, seating parts 312a and 312b may be formed on a surface of the support body 312, and the wire 313 may be contracted or may be relaxed, and the wire 313 deformed in a state in which at least a portion of the wire 313 is seated in or accommodated in the seating parts 312a and 312b. According to an embodiment, the seating parts 312a and 312b may include a recess formed on the side surface of the support body 312.

In an embodiment and referring to FIG. 12A and FIG. 12B, another method for securing immediacy in an opening operation and/or a restoring operation by using the automatic opening module of the electronic device may be disclosed. According to an embodiment, multiple shape memory alloy wires 313 may be used therefor. When the multiple shape memory alloy wires 313 are used, the force pulling the support body 312 and the magnetic body array 311 may be distributed to each of the wires, thereby reducing the diameter of each of the wires.

According to an embodiment, in the case where the diameter of each of the wires is reduced, a surface area to density thereof may be increased and thus the contraction speed or the relaxation/deformation speed of the wires according to a temperature change may be increased, thereby enhancing immediacy in an operation. According to an embodiment, as illustrated in FIG. 12B, the multiple wires may be arranged to have distances therebetween, each of which is greater than the diameter of each of the wires to minimize influence between adjacent wires. For example, when the multiple shape memory alloy wires are formed in a combined (e.g., twist) form, the effect of shape deformation according to temperature change may be reduced. Therefore, as illustrated in FIG. 12B, it may be preferable that the wires are separate from each other. The following Table shows various combinations of the shape memory alloy wires, and it is possible to identify the differences in the contraction speed and the relaxation speed according to each of the combinations.

TABLE 2

| | | Shape memory alloy module/wire | | | | | | | |
|---|---|---|---|---|---|---|---|---|---|
| | | Speed during contraction | | | | Speed during relaxation | | | |
| | | (heating/Austenite) | | | | (cooling/Martensite) | | | |
| | Temperature | (Unit: second) | | | | (Unit: second) | | | |
| Condition | environment | 1 | 2 | 3 | Avg | 1 | 2 | 3 | Avg |
| One wire having | 60° C. | 0.59 | 0.65 | 0.69 | 0.64 | 7.54 | 7.81 | 7.43 | 7.59 |
| diameter of 250 μm | | | | | | | | | |
| Combined two wires | 60° C. | 1.48 | 1.35 | 1.47 | 1.43 | 5.10 | 5.50 | 5.40 | 5.33 |
| each having diameter | | | | | | | | | |
| of 125 μm | | | | | | | | | |
| Separated two wires | 60° C. | 1.38 | 1.58 | 1.43 | 1.46 | 3.18 | 3.47 | 3.34 | 3.33 |
| each having diameter | | | | | | | | | |
| of 125 μm | | | | | | | | | |

In an embodiment, Table 2 above is a table showing comparison between the speeds during contraction and the speeds during relaxation, according to an embodiment, in which one shape memory alloy wire having a diameter of about 250 μm is applied thereto, an embodiment in which two shape memory alloy wires, each of which has a diameter of about 125 μm and which are combined, are applied thereto, and an embodiment in which two shape memory alloy wires, each of which has a diameter of about 125 μm and which are separated, are applied thereto. Since the shape memory alloy has a movement mechanism contracted and relaxed by heat as a parameter, the speed during contraction and the speed during relaxation may have a trade-off relationship with each other according to the size relation of the diameter.

When taking this into account, according to an embodiment, as a method for improving usability of the automatic opening module of the electronic device, an embodiment for significantly improving the speed during relaxation may be applied thereto although having somewhat disadvantage in the speed during contraction. For example, referring to Table 2, in the case where one shape memory alloy wire having a diameter of about 250 μm is applied thereto, it may be identified that the speed during contraction is the fastest, but the speed during relaxation is about 7 seconds or more. In the case of an electronic device to which the one shape memory alloy wire having a diameter of about 250 μm is applied, it may mean that it takes 7 seconds or more in the process of restoring (e.g., closed) after opening (e.g., open). Referring again to Table 2, under the same temperature condition, an embodiment, to which one shape memory alloy wire having a large diameter is applied, may have a speed during relaxation faster than that of an embodiment to which two combined shape memory alloy wires are applied. Furthermore, it may be identified that an embodiment, to which two separated shape memory alloy wires are applied, has the fastest speed during relaxation. The speed during contraction according to an embodiment, to which two shape memory alloy wires each having a diameter of about 125 μm are applied, may take longer by approximately 0.8 seconds to about 0.9 seconds than that of an embodiment to which one shape memory alloy wire having a diameter of about 250 ums is applied. However, the speed during relaxation may be reduced by approximately about 2 seconds to about 5 seconds or more. When taking this into account, according to an embodiment, two wires having a small diameter may be used instead of using one wire having a large diameter, and although two wires having a small diameter are applied thereto, the separated shape may be applied instead of a combined shape, thereby enhancing immediacy in the opening speed and/or the restoring speed of the electronic device.

Although FIG. 12A and FIG. 12B illustrate two wires as multiple wires, it should be noted that embodiments including three, or four or more wires are also applied thereto.

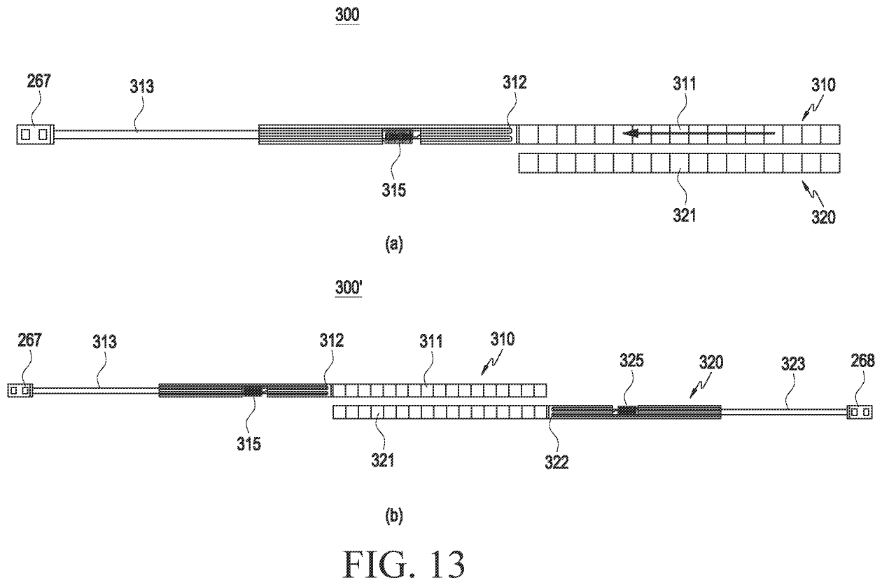

FIG. 13A is a view illustrating automatic opening modules 300, according to an embodiment. FIG. 13B is a view illustrating automatic opening modules 300′, according to an embodiment.

In an embodiment and referring to FIG. 13A and FIG. 13B, the automatic opening modules 300 and 300′ may include at least one movable magnetic body module. The automatic opening module may include the shape memory alloy member, the support body 312 to which the shape memory alloy member may be caught and supported, the spring 315 capable of restoring the movable magnetic body module back to the original position thereof, and one pair of magnetic body arrays which may influence each other through attractive force and repulsive force. FIG. 13A illustrates an embodiment provided with one movable magnetic body module 310 and one stationary magnetic body 320, and FIG. 13B illustrates an embodiment provided with one pair of movable magnetic body modules 310 and 320. Referring to FIG. 13B, when the movable magnetic body module is provided as one pair, the magnetic body arrays 311 and 321 may be arranged at positions corresponding to each other, and other elements may be arranged to face opposite directions. For example, the first support body 312, the shape memory alloy wire 313, the spring 315, and the feeder 267 of the first movable magnetic body module 310 may be arranged to face the longitudinal direction (e.g., the Y-axis direction) of the electronic device (e.g., the electronic device 200 of FIG. 9), and the second support body 322, the shape memory alloy wire 323, the spring 325, and the feeder 268 of the second movable magnetic body module 320 may be arranged to face a direction opposite to the longitudinal direction (e.g., a direction opposite to the Y-axis) of the electronic device (e.g., the electronic device 200 of FIG. 9). As illustrated in FIG. 13B, when the automatic opening module 300′ is configured as one pair of movable magnetic body modules, the contraction and relaxation operations by using the shape memory alloy member may be simultaneously operated in one direction (e.g., the Y-axis direction) and in the opposite direction (e.g., a direction opposite to the Y-axis), respectively. Therefore, the speed of the opening operation and/or the restoring operation may be faster so that it is advantageous to secure immediacy.

FIG. 14A to FIG. 14F are views illustrating various folded states of an electronic device and the tilt thereof with respect to the direction of gravity, according to an embodiment.

In an embodiment, a foldable electronic device 200 capable of being carried by a user, may be positioned in various states according to a user's grip state differently from laptop computers. In addition, different gravities may be applied thereto depending on the tilting state of the electronic device, and thus the hinge driving force for opening a terminal may vary according to the tilting state of the electronic device.

Therefore, according to an embodiment, the degree of tilt of the electronic device may be sensed using a sensor (e.g., the acceleration sensor) capable of detecting the tilt thereof, the positioning of a terminal may be determined based on the sensed tilt, and then a voltage may be changed and then supplied to respond to the change of the hinge driving force due to the influence of gravity, thereby preventing malfunction and reducing power consumption.

In an embodiment and as illustrated in FIGS. 14A and 14B, considering the direction of gravity G, when the electronic device 200 is positioned in a horizontal direction with respect to the ground, it may be determined that the hinge driving force required to open the electronic device 200 is great, and thus a voltage higher than an average voltage may be supplied thereto in order for rapid opening thereof.

In an embodiment, as illustrated in FIGS. 14C, 14D, and 14E, considering the direction of gravity G, when the electronic device 200 is positioned in a vertical direction with respect to the ground, it may be determined that the hinge driving force required to open the electronic device 200 is small, and thus a voltage lower than an average voltage may be supplied thereto.

In an embodiment, as illustrated in FIG. 14F, considering the direction of gravity G, when the electronic device 200 is obliquely tilted with respect to the ground, it may be determined that the hinge driving force required to open the electronic device 200 is smaller than those of FIGS. 14A and 14B and greater than those of FIGS. 14C, 14D, and 14E, and thus an average voltage may be supplied thereto.

According to an embodiment, data on the degree of tilt of the electronic device may change in real time, and thus it may be necessary to obtain and correct data for a predetermined time period. Accordingly, the processor (e.g., the processor 120 of FIG. 1) may accumulate data for a predetermined time before feeding to the shape memory alloy member, and may perform a correction by using various algorithms. In this case, according to an embodiment, when feeding is performed to the shape memory alloy member, the processor may be configured such that power is gradually applied thereto so as to control the temperature rise speed thereof, thereby preventing a sudden operation thereof. Therefore, the load, to which the shape memory alloy member can be subjected due to the rapid operation thereof, may be reduced to prevent shortening of life.

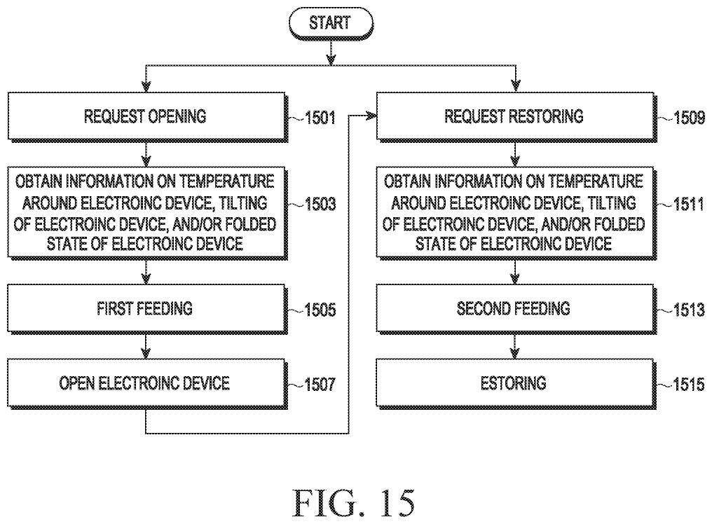

FIG. 15 is a flowchart of a control method of a foldable electronic device (e.g., the foldable electronic device 200 of FIG. 4), according to an embodiment.

According to an embodiment, a control method of a foldable electronic device including the processor and the automatic opening module (e.g., the automatic opening module 300 of FIG. 4) configured to perform an opening operation of the first housing structure with respect to the second housing structure, by using the shape memory alloy member (e.g., the shape memory alloy member 313 FIG. 6) disposed in at least one of the first housing structure (e.g., the first housing structure 210 of FIG. 9) or the second housing structure (e.g., the second housing structure 220 of FIG. 9), may be provided.

Each of the operations, according to an embodiment illustrated in FIG. 15, may be performed by the processor (e.g., the processor 263 of FIG. 9). Each of operations illustrated in FIG. 15, as an example thereof, may be described through an embodiment in which the movable magnetic body module (e.g., the movable magnetic body module 310 of FIG. 9) and the stationary magnetic body (e.g., the stationary magnetic body 320 of FIG. 9) are respectively arranged in the first housing structure 210 and second housing structure 220, and when the foldable electronic device is closed (e.g., the closed state of FIG. 3), attractive force is applied between the movable magnetic body module 310 and the stationary magnetic body 320. It should be noted that each of operations illustrated in FIG. 15 may be also applied to other various embodiments falling within the scope of the disclosure.

In an embodiment, in relation to operation 1501, an opening request for the foldable electronic device may be input. The “opening request” may include various embodiments. For example, the “opening request” may correspond to an input to the electronic device (e.g., an execution of an application and/or an input to a key input device such as a button) by a user, or an electronic device opening operation algorithm pre-stored in the electronic device.

In an embodiment and in relation to operation 1503, for example, when the opening request is inputted, the processor may obtain information on at least one element among the temperature of or around the electronic device, the tile of the electronic device with respect to the direction of gravity, and/or the folded state of the electronic device, from the sensor capable of detecting the folding angle of the electronic device (e.g., the angle sensor 264 of FIG. 9), the sensor (e.g., the temperature sensor 265 of FIG. 9) capable of detecting a change in temperature of or around the electronic device, and/or the sensor (not shown) capable of detecting the tilt of the electronic device with respect to the direction of gravity.

In an embodiment and in relation to operation 1505, the processor may perform first feeding, based on at least one element among the temperature of or around the electronic device, the tilt of the electronic device with respect to the direction of gravity, and the folded state of the electronic device. Here, the “first feeding” may mean controlling power supplied to the shape memory alloy (SMA) member (e.g., the shape memory alloy wire 513 of FIG. 6) in the opening operation, and/or the supply time period of power.

In an embodiment and in relation to operation 1507, when the first feeding is performed to the shape memory alloy wire 513, the shape memory alloy wire 513 may be contracted so that the movable magnetic body module 310 moves, and thus attractive force applied between the movable magnetic body module 310 and the stationary magnetic body 320 may be removed. According to an embodiment, the attractive force may be removed according to the amount of movement of the movable magnetic body module 310, and also repulsive force may be applied between the movable magnetic body module 310 and the stationary magnetic body 320. When attractive force between the movable magnetic body module 310 and the stationary magnetic body 320 is removed, alternatively or additionally, by the repulsive force of the flexible display 250, the first housing structure 210 and the second housing structure 220 may be automatically opened without any additional force by a user. Summarizing operations 1501 to 1507, when only the opening request is input, the foldable electronic device according to various embodiments may be configured to implement an easy-opening operation of automatically opening the first housing structure 210 and the second housing structure 220 by a predetermined angle θ (or a predetermined distance), thereby improving user convenience.

In an embodiment, the foldable electronic device 200 may perform a restoring operation following the opening operation, or through an input separated from the opening operation.

In relation to operation 1509, a restoring request for the foldable electronic device may be input. The “restoring request” may include various embodiments. For example, the “restoring request” may correspond to an input to the electronic device (e.g., an execution of an application and/or an input to a key input device such as a button) by a user, or an electronic device restoring operation algorithm pre-stored in the electronic device. For another example, the restoring operation algorithm may include an algorithm configured to be automatically performed after a predetermined time elapses after the electronic device is opened according to operation 1507.

In an embodiment and in relation to operation 1511, for example, when the restoring request is inputted, the processor may obtain information on at least one element among the temperature of or around the electronic device, the tile of the electronic device with respect to the direction of gravity, and/or the folded state of the electronic device, from the sensor capable of detecting the folding angle of the electronic device (e.g., the angle sensor 264 of FIG. 9), the sensor (e.g., the temperature sensor 265 of FIG. 9) capable of detecting a change in temperature of or around the electronic device, and/or the sensor (not shown) capable of detecting the tilt of the electronic device with respect to the direction of gravity.

In an embodiment and in relation to operation 1513, the processor may perform second feeding, based on at least one element among the temperature of or around the electronic device, the tilting state of the electronic device with respect to the direction of gravity, and the folding state of the electronic device. Here, the “second feeding” may mean controlling power supplied to the shape memory alloy member 513 in the restoring operation, and/or the supply time period of power. The second feeding may be different from the aforementioned first feeding. For example, as described above through Table 1, it may be identified that in the opening operation, the contraction speed of the wire is faster as the voltage is higher, and it may be identified that in the restoring operation, the relaxation speed of the wire is slower as the voltage is higher. Considering that the wire is relaxed in the restoring operation, a voltage (or current), which is a level different from that in the first feeding, may be applied thereto.

In an embodiment and in relation to operation 1515, when the second feeding is performed to the shape memory alloy wire 513, the shape memory alloy wire 513 may be relaxed so that the movable magnetic body module 310 may move. According to an embodiment, the “restoring operation” of the foldable electronic device 200 may mean an operation of restoring the electronic device from an open state (e.g., the open state of the FIG. 2, or the open state of the FIG. 5A) to a closed state (e.g., the closed state of the. FIG. 3). However, the invention is not limited thereto, and according to another embodiment, it may mean that only the movable magnetic body module 310 returns to the original state according to the relaxation of the shape memory alloy wire 513. For example, the restoring of the electronic device from an open state to a closed state may mean restoring to a state in which the side surface (e.g., the first side surface 211a in FIG. 9) of the first housing structure 210 and the side surface (e.g., the second side surface 221a of FIG. 9) of the second housing structure 220 are in contact with each other by attractive force applied between the movable magnetic body module 310 and the stationary magnetic body module 320. In another embodiment, the restoring of only the movable magnetic body module 310 to the original state may mean restoring to a state in which the first housing structure 210 and the second housing structure 220 are not in contact with each other although the movable magnetic body module 310 is restored to the original position. According to an embodiment, by “being restored” according to operation 1515, the foldable electronic device 200 may become a closed state in which the first housing structure 210 and the second housing structure 220 are in contact with each other. In another embodiment, the foldable electronic device may become a state in which the foldable electronic device can be easily closed by the user (e.g., a state in which attractive force may be applied between the movable magnetic body module 310 and the stationary magnetic body 320) although the first housing structure 210 and the second housing structure 220 of the foldable electronic device 200 are not in contact with each other.

In addition, the electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B”, “at least one of A and B”, “at least one of A or B”, “A, B, or C”, “at least one of A, B, and C”, and “at least one of A, B, or C”, may include any one of, or all possible combinations of the items enumerated together in a corresponding one of the phrases. As used herein, such terms as “1st” and “2nd”, or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with”, “coupled to”, “connected with”, or “connected to” another element (e.g., a second element), it means that the element may be coupled with the other element directly (e.g., wiredly), wirelessly, or via a third element.

As used in connection with various embodiments of the disclosure, the term “module” may include a unit implemented in hardware, software, or firmware, and may interchangeably be used with other terms, for example, “logic”, “logic block”, “part”, or “circuitry”. A module may be a single integral component, or a minimum unit or part thereof, adapted to perform one or more functions. For example, according to an embodiment, the module may be implemented in a form of an application-specific integrated circuit (ASIC).

According to various embodiments, each component (e.g., a module or a program) of the above-described components may include a single entity or multiple entities, and some of the multiple entities may be separately disposed in different components. According to various embodiments, one or more of the above-described components or operations may be omitted, or one or more other components or operations may be added. Alternatively or additionally, a plurality of components (e.g., modules or programs) may be integrated into a single component. In such a case, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

According to an embodiment, a foldable electronic device may be provided, wherein the foldable electronic device (e.g., the foldable electronic device 200 of FIG. 4) includes a hinge structure (e.g., the hinge structure 230 of FIG. 4), a first housing structure (e.g., the first housing structure 210 of FIG. 4) connected to the hinge structure, a second housing structure (e.g., the second housing structure 220 of FIG. 4) connected to the hinge structure and configured to be foldable with respect to the first housing structure around the hinge structure, a foldable display (e.g., the foldable display 250 of FIG. 2) disposed on a surface of the first housing structure and a surface of the second housing structure, a first magnetic body part (e.g., the first magnetic body part 310 of FIG. 4) including a magnetic body which is disposed at a position adjacent to a side edge of the first housing structure and arranged along the longitudinal direction of the first housing structure, a second magnetic body part (e.g., the second magnetic part 320 of FIG. 4) including a magnetic body which is disposed at a position adjacent to a side edge of the second housing structure and at a position corresponding to the first magnetic body part and arranged along the longitudinal direction of the second housing structure, and a power supply circuit (e.g., the shape memory alloy (SAM) controller 266 of FIG. 9), wherein at least one of the first magnetic body part or the second magnetic body part is electrically connected to the power supply circuit and formed as a movable magnetic body module including a shape memory alloy member capable of being deformed and restored along the longitudinal direction of the electronic device.

According to an embodiment, the movable magnetic body module may include a magnetic body array (e.g., the magnetic body array 311 of FIG. 6), a support body (e.g., the support body 312 of FIG. 6) provided at a side of the magnetic body array, a shape memory alloy wire (e.g., the shape memory alloy wire 313 of FIG. 6) which is electrically connected to the power supply circuit and is capable of being contracted or relaxed in a state where at least a part thereof is supported to the support body, and a spring (e.g., the spring 315 of FIG. 6) configured to restore the movable magnetic body module.

According to an embodiment, a feeder (e.g., the feeder 267 of FIG. 6), which is disposed in the longitudinal direction of the movable magnetic body module to be connected to the shape memory alloy wire, may be included therein.

According to an embodiment, the magnetic body array may include a Halbach arrangement (e.g., the Halbach arrangement of FIG. 7).

According to an embodiment, the shape memory alloy wire may be formed to be seated in a recess (e.g., the seating parts 312a and 312b of FIG. 12B) formed on a side surface of the support body.

According to an embodiment, the shape memory alloy wire may include multiple wires arranged to be parallel to each other along the longitudinal direction of the movable magnetic body module.

According to an embodiment, the distance between the multiple wires may be formed to be greater than the diameter of each of the wires.

According to an embodiment, the first magnetic body part and the second magnetic body part may be respectively formed as movable magnetic body modules (e.g., the movable magnetic body modules 310 and 320 of FIG. 13B) arranged to face directions opposite to each other.

According to an embodiment, a first battery (e.g., the first battery 261 of FIG. 9) may be included in the inner space of the first housing structure, the first magnetic body part may be disposed in a space between the first battery and the first housing structure, a second battery (e.g., the second battery 262 of FIG. 9) may be included in the inner space of the second housing structure, and the second magnetic body part may be disposed in a space between the second battery and the second housing structure.

According to an embodiment, a sensor (e.g., the sensor 264 of FIG. 9) capable of detecting a folding angle between the first housing structure and the second housing structure may be further included therein.

According to an embodiment, a sensor capable of detecting tilting of the electronic device with respect to the direction of gravity may be further included therein.

According to an embodiment, a sensor (e.g., the sensor 265 of FIG. 9) configured to detect a temperature change of the electronic device or around the electronic device may be further included therein.

According to an embodiment, a processor (e.g., the processor 263 of FIG. 9) may be further included therein, wherein the processor may be configured to adjust the magnitude of power and/or a supply time period of power supplied to the shape memory alloy member, based on at least one element of a temperature of or around the electronic device, the tilting state of the electronic device with respect to the direction of gravity, and the folding state of the electronic device.

According to an embodiment, a control method of a foldable electronic device may be provided, wherein the control method of a foldable electronic device includes a first housing structure and a second housing structure foldable with respect to the first housing structure, and includes a processor and an automatic opening module configured to perform an opening operation of the first housing structure with respect to the second housing structure, by using a magnetic body part disposed in each of the first housing structure and the second housing structure and a shape memory alloy member disposed in at least one of the first housing structure or the second housing structure, wherein the processor is configured to adjust power and/or a supply time period of power supplied to the shape memory alloy member, based on at least one element of a temperature of or around the electronic device, the tilting state of the electronic device with respect to the direction of gravity, and the folding state of the electronic device.

According to an embodiment, the magnetic body part may include a magnetic body array having a Halbach arrangement, the processor may be configured to supply power for moving the shape memory alloy member such that attractive force between the magnetic body parts respectively arranged in the first housing structure and the second housing structure is removed.

According to an embodiment, a foldable electronic device (e.g., the foldable electronic device 200 of FIG. 4) may be provided, wherein the foldable electronic device may include a hinge structure (e.g., the hinge structure 230 of FIG. 4) configured to form a folding axis, a first housing structure (e.g., the first housing structure 210 of FIG. 4) which is connected to the hinge structure to be rotatable around the folding axis and includes a first surface configured to face a first direction (e.g., the +Z direction of FIG. 4), a second surface configured to face a second direction (e.g., the −Z direction of FIG. 4) opposite to the first direction, and a first side surface (e.g., the first side surface 211a of FIG. 9) disposed to be parallel to and spaced apart from the folding axis of the hinge structure, between the first surface and the second surface, a second housing structure (e.g., the second housing structure 220 of FIG. 4) which is connected to the hinge structure to be rotatable around the folding axis and includes a third surface configured to face a third direction (e.g., the +Z direction of FIG. 4), a fourth surface configured to face a fourth direction (e.g., the −Z direction of FIG. 4) opposite to the third direction, and a second side surface (e.g., the second side surface 221a of FIG. 9) disposed to be parallel to and spaced apart from the folding axis of the hinge structure, between the third surface and fourth surface, a foldable display (e.g., the foldable display 250 of FIG. 2) disposed on a surface of the first housing structure and a surface of the second housing structure, a power supply circuit (e.g., the SMA controller 266 of FIG. 9), a movable magnetic body module (e.g., the movable magnetic body module 310 of FIG. 9) including a magnetic bodies which are arranged at a position adjacent to the first side surface of the first housing structure and arranged along the longitudinal direction of the first housing structure, and a shape memory alloy member which is electrically connected to the power supply circuit and is capable of being deformed or restored along the longitudinal direction of the electronic device, and a stationary magnetic body (e.g., the stationary magnetic body 320 of FIG. 9) disposed at a position adjacent to a second side surface of the second housing structure and at a position corresponding to the first magnetic body part and arranged along the longitudinal direction of the second housing structure.

According to an embodiment, the movable magnetic body module may include a magnetic body array (e.g., the magnetic body array 311 of FIG. 6), a support body (e.g., the support body 312 of FIG. 6) provided at a side of the magnetic body array, a shape memory alloy wire (e.g., the shape memory alloy wire 313 of FIG. 6) which is electrically connected to the power supply circuit and is capable of being contracted or relaxed in a state where at least a part thereof is supported to the support body, and a spring (e.g., the spring 315 of FIG. 6) configured to restore the movable magnetic body module.

According to an embodiment, a feeder (e.g., the feeder 267 of FIG. 6), which is disposed in the longitudinal direction of the movable magnetic body module to be connected to the shape memory alloy wire, may be included therein.

According to an embodiment, the shape memory alloy wire may include multiple wires arranged to be parallel to each other along the longitudinal direction of the movable magnetic body module, and the distance between the multiple wires may be formed to be greater than the diameter of each of the wires.

According to an embodiment, a processor (e.g., the processor 263 of FIG. 9) may be further included therein, wherein the processor may be configured to adjust the magnitude of power and/or a supply time period of power supplied to the shape memory alloy member, based on at least one element of a temperature of or around the electronic device, the tilting state of the electronic device with respect to the direction of gravity, and the folding state of the electronic device.

Although specific embodiments are described in the above detailed description, it will be obvious to a person skilled in the art that various changes are possible within the range without departing from the scope of the invention.

1. A foldable electronic device comprising:
a hinge structure;
a first housing structure connected to the hinge structure;
a second housing structure connected to the hinge structure and configured to be foldable with respect to the first housing structure around the hinge structure;
a foldable display disposed on a surface of the first housing structure and a surface of the second housing structure;
a first magnetic body part comprising a magnetic body which is disposed at a position adjacent to a side edge of the first housing structure and which is arranged along a longitudinal direction of the first housing structure;
a second magnetic body part comprising a magnetic body which is disposed at a position adjacent to a side edge of the second housing structure and at a position corresponding to the first magnetic body part and arranged along a longitudinal direction of the second housing structure; and
a power supply circuit,
wherein at least one of the first magnetic body part or the second magnetic body part is electrically connected to the power supply circuit and formed as a movable magnetic body module comprising a shape memory alloy member capable of being deformed or restored along a longitudinal direction of the electronic device.

2. The foldable electronic device of claim 1, wherein
the movable magnetic body module comprises:
a magnetic body array;
a support body provided at a side of the magnetic body array;
a shape memory alloy wire which is electrically connected to the power supply circuit and which is configured to be contracted or relaxed in a state where at least a part thereof is supported to the support body; and
a spring configured to restore the movable magnetic body module.

3. The foldable electronic device of claim 2, comprising
a feeder disposed in a longitudinal direction of the movable magnetic body module to be connected to the shape memory alloy wire.

4. The foldable electronic device of claim 2, wherein
the magnetic body array comprises a Halbach arrangement.

5. The foldable electronic device of claim 2, wherein
the shape memory alloy wire is formed to be seated in a recess formed on a side surface of the support body.

6. The foldable electronic device of claim 2, wherein
the shape memory alloy wire comprises multiple wires arranged to be disposed parallel to each other along a longitudinal direction of the movable magnetic body module, and a distance between the multiple wires is greater than a diameter of each of the multiple wires.

7. The foldable electronic device of claim 1, wherein
the first housing structure and the second housing structure are configured to be opened by a designated folding angle by a cam of the hinge structure when an attractive force between the first magnetic body part and the second magnetic body part is removed.

8. The foldable electronic device of claim 1, wherein
the first magnetic body part and the second magnetic body part are respectively formed as movable magnetic body modules arranged to face directions opposite to each other.

9. The foldable electronic device of claim 1, wherein
a first battery is included in an inner space of the first housing structure,
wherein the first magnetic body part is disposed in a space between the first battery and the first housing structure, and
wherein a second battery is included in the inner space of the second housing structure, and
wherein the second magnetic body part is disposed in a space between the second battery and the second housing structure.

10. The foldable electronic device of claim 1, further comprising
a sensor for detecting a folding angle between the first housing structure and the second housing structure.

11. The foldable electronic device of claim 1, further comprising
a sensor configured to detect a tilting state of the electronic device with respect to a direction of gravity.

12. The foldable electronic device of claim 1, further comprising
a sensor configured to detect a temperature change of the electronic device or an area around the electronic device.

13. The foldable electronic device of claim 1, further comprising
a processor, wherein
the processor is configured to adjust at least one of a magnitude of power or a supply time period of power supplied to the shape memory alloy member, based on at least one element of a temperature of or around the electronic device, a tilting state of the electronic device with respect to a direction of gravity, and a folding state of the electronic device.

14. The foldable electronic device of claim 2, further comprising
a processor, wherein the processor is configured to adjust the magnitude of power and/or a supply time period of power supplied to the shape memory alloy member, based on at least one element of the temperature of or around the electronic device, the tilting of the electronic device with respect to the direction of gravity, and the folding state of the electronic device.

15. A control method of a foldable electronic device comprising:
obtaining at least one of a temperature of or around the electronic device, a tilting state of the electronic device with respect to a direction of gravity, and a folding state of the electronic device, wherein the electronic device comprises a first housing structure, a second housing structure foldable with respect to the first housing structure, at least one processor, an automatic opening module configured to perform an opening operation of the first housing structure with respect to the second housing structure, by using a magnetic body part disposed in each of the first housing structure and the second housing structure. and a shape memory alloy member disposed in at least one of the first housing structure or the second housing structure,
adjusting at least one of power or a supply time period of power supplied to the shape memory alloy member, based on at least one element of a temperature of or around the electronic device, a tilting state of the electronic device with respect to a direction of gravity, and a folding state of the electronic device.

16. The control method of claim 15, comprising:
supplying power for moving the shape memory alloy member such that an attractive force between the magnetic body part arranged in the first housing structure and the second housing structure is removed,
wherein the magnetic body part comprises a magnetic body array having a Halbach arrangement.

17. A foldable electronic device comprising:
a hinge structure configured to form a folding axis;
a first housing structure which is connected to the hinge structure to be rotatable around the folding axis and comprises: a first surface configured to face a first direction; a second surface configured to face a second direction opposite to the first direction; and a first side surface disposed to be parallel to and spaced apart from the folding axis of the hinge structure, between the first surface and the second surface;
a second housing structure which is connected to the hinge structure to be rotatable around the folding axis and comprises: a third surface configured to face a third direction; a fourth surface configured to face a fourth direction opposite to the third direction; and a second side surface disposed to be parallel to and spaced apart from the folding axis of the hinge structure, between the third surface and fourth surface;
a foldable display disposed on a surface of the first housing structure and a surface of the second housing structure;
a power supply circuit;
a movable magnetic body module comprising a magnetic body which is disposed at a position adjacent to the first side surface of the first housing structure and arranged along the longitudinal direction of the first housing structure, and a shape memory alloy member which is electrically connected to the power supply circuit and is capable of being deformed or restored along the longitudinal direction of the electronic device; and
a stationary magnetic body disposed at a position adjacent to a second side surface of the second housing structure and at a position corresponding to the first magnetic body part and arranged along the longitudinal direction of the second housing structure.

18. The foldable electronic device of claim 17,
wherein
the movable magnetic body module comprises:
a magnetic body array;
a support body provided at a side of the magnetic body array;
a shape memory alloy wire which is electrically connected to the power supply circuit and is configured to be contracted or relaxed in a state where at least a part thereof is supported to the support body; and
a spring configured to restore the movable magnetic body module.

19. The foldable electronic device of claim 17, further comprising
a feeder disposed in the longitudinal direction of the movable magnetic body module to be connected to the shape memory alloy wire.

20. The foldable electronic device of claim 19, wherein
the shape memory alloy wire comprises multiple wires arranged to be parallel to each other along the longitudinal direction of the movable magnetic body module, and
the distance between the multiple wires is formed to be greater than the diameter of each of the wires.
